(19) United States
(12) Patent Application Publication
(10) Pub. No.: US 2016/0322554 A1
(43) Pub. Date: Nov. 3, 2016

(54) ELECTRODE STRUCTURES FOR ARRAYS OF NANOSTRUCTURES AND METHODS THEREOF

(71) Applicant: Alphabet Energy, Inc., Hayward, CA (US)

(72) Inventors: Matthew L. Scullin, San Francisco, CA (US); Madhav A. Karri, Berkeley, CA (US); Adam Lorimer, Walnut Creek, CA (US); Sylvain Muckenhirn, Santa Barbara, CA (US); Gabriel A. Matus, San Francisco, CA (US); Justin Tynes Kardel, Oakland, CA (US); Barbara Wacker, Saratoga, CA (US)

(21) Appl. No.: 15/089,190

(22) Filed: Apr. 1, 2016

Related U.S. Application Data
(63) Continuation of application No. 13/364,176, filed on Feb. 1, 2012, now abandoned.
Application No. 13/364,176 is a continuation of application No. 13/331,768, filed on Dec. 20, 2011, now abandoned.
(60) Provisional application No. 61/438,709, filed on Feb. 2, 2011.
(60) Provisional application No. 61/425,362, filed on Dec. 21, 2010.

(51) Int. Cl. H01L 35/32; H01L 35/34; H01L 35/26

(52) U.S. Cl. CPC H01L 35/32; H01L 35/26; H01L 35/34; B82Y 30/00

(57) ABSTRACT

A thermoelectric device and methods thereof. The thermoelectric device includes nanowires, a contact layer, and a shunt. Each of the nanowires includes a first end and a second end. The contact layer electrically couples the nanowires through at least the first end of each of the nanowires. The shunt is electrically coupled to the contact layer. All of the nanowires are substantially parallel to each other. A first contact resistivity between the first end and the contact layer ranges from 10⁻¹³ Ω-m² to 10⁻⁷ Ω-m². A first work function between the first end and the contact layer is less than 0.8 electron volts. The contact layer is associated with a first thermal resistance ranging from 10⁻² K/W to 10¹⁰ K/W.

### CROSS-REFERENCES TO RELATED APPLICATIONS

This application is a continuation under 35 U.S.C. §120 of U.S. patent application Ser. No. 13/364,176, filed Feb. 1, 2012 and entitled “Electrode Structures for Arrays of Nanostructures and Methods Thereof,” which claims priority to U.S. Provisional Application No. 61/438,709, filed Feb. 2, 2011, both of which applications are commonly assigned and incorporated by reference herein for all purposes. This application is also a continuation-in-part of U.S. patent application Ser. No. 13/331,768, filed Dec. 20, 2011, which claims priority to U.S. Provisional Application No. 61/425,362, filed Dec. 21, 2010, commonly assigned and incorporated by reference herein for all purposes.

Additionally, this application is related to U.S. patent application Ser. Nos. 13/299,179 and 13/308,945, which are incorporated by reference herein for all purposes.

### STATEMENT OF GOVERNMENT INTEREST

This invention was made with government support under (1) SBIR Contract No. W911QY-10-C-0063 awarded by the U.S. Army, and (2) SBIR Contract No. W11QY-11-C-0027 awarded by the U.S. Army. The Government has certain rights in the invention.

### BACKGROUND OF THE INVENTION

The present invention is directed to nanostructures. More particularly, the invention provides electrode structures for arrays of nanostructures and methods thereof. Merely by way of example, the invention has been applied to arrays of nanostructures embedded in one or more fill materials with electrode structures for use in thermoelectric devices. However, it would be recognized that the invention has a much broader range of applicability, including but not limited to use in solar power, battery electrodes and/or energy storage, catalysis, and/or light emitting diodes.

Thermoelectric materials are ones that, in the solid state and with no moving parts, can, for example, convert an appreciable amount of thermal energy into electricity in an applied temperature gradient (e.g., the Seebeck effect) or pump heat in an applied electric field (e.g., the Peltier effect). The applications for solid-state heat engines are numerous, including the generation of electricity from various heat sources whether primary or waste, as well as the cooling of spaces or objects such as microchips and sensors. Interest in the use of thermoelectric devices that comprise thermoelectric materials has grown in recent years in part due to advances in nano-structured materials with enhanced thermoelectric performance (e.g., efficiency, power density, or “thermoelectric figure of merit” ZT, where ZT is equal to S² σ/k and S is the Seebeck coefficient, σ the electrical conductivity, and k the thermal conductivity of the thermoelectric material) and also due to the heightened need both for systems that either recover waste heat as electricity to improve energy efficiency or cool integrated circuits to improve their performance.

To date, thermoelectrics have had limited commercial applicability due to the poor cost performance of these devices compared to other technologies that accomplish similar means of energy generation or refrigeration. Where other technologies usually are not as suitable as thermoelectrics for use in lightweight and low footprint applications, thermoelectrics often have nonetheless been limited by their prohibitively high costs. Important in realizing the usefulness of thermoelectrics in commercial applications is the manufacturability of devices that comprise high-performance thermoelectric materials (e.g., modules). These modules are preferably produced in such a way that ensures, for example, maximum performance at minimum cost.

The thermoelectric materials in presently available commercial thermoelectric modules are generally comprised of bismuth telluride or lead telluride, which are both toxic, difficult to manufacture with, and expensive to procure and process. With a strong present need for both alternative energy production and microscale cooling capabilities, the driving force for highly manufacturable, low cost, high performance thermoelectrics is growing.

Thermoelectric devices are often divided into thermoelectric legs made by conventional thermoelectric materials such as Bi₂Te₃ and PbTe, contacted electrically, and assembled in a refrigeration (e.g., Peltier) or energy conversion (e.g., Seebeck) device. This often involves bonding the thermoelectric legs to metal contacts in a configuration that allows a series-configured electrical connection while providing a thermally parallel configuration, so as to establish a temperature gradient across all the legs simultaneously. However, many drawbacks may exist in the production of conventional thermoelectric devices. For example, costs associated with processing and assembling the thermoelectric legs made externally is often high. The conventional processing or assembling method usually makes it difficult to manufacture compact thermoelectric devices needed for many thermoelectric applications. Conventional thermoelectric materials are usually toxic and expensive.

Nanostructures often refer to structures that have at least one structural dimension measured on the nanoscale (e.g., between 0.1 nm and 1000 nm). For example, a nanowire is characterized as having a cross-sectional area that has a distance across that is measured on the nanoscale, even though the nanowire may be considerably longer in length. In another example, a nanotube, or hollow nanowire, is characterized by having a wall thickness and total cross-sectional area that has a distance across that is measured on the nanoscale, even though the nanotube may be considerably longer in length. In yet another example, a nanohole is characterized as a void having a cross-sectional area that has a distance across that is measured on the nanoscale, even though the nanohole may be considerably longer in depth. In yet another example, a nanomesh is an array, sometimes interlinked, including a plurality of other nanostructures such as nanowires, nanotubes, and/or nanoholes.

Nanostructures have shown promise for improving thermoelectric performance. The creation of 0D, 1D, or 2D nanostructures from a thermoelectric material may improve the thermoelectric power generation or cooling efficiency of that material in some instances, and sometimes very significantly (a factor of 100 or greater) in other instances. However, many limitations exist in terms of alignment, scale, and mechanical strength for the nanostructures needed in an actual macroscopic thermoelectric device comprising many nanostructures. Processing such nanostructures using methods that are similar to the processing of silicon would have tremendous cost advantages. For example, creating nanostructure arrays with planar surfaces supports planar semiconductor processes like metalization.

Hence, it is highly desirable to form these arrays of nanostructures from materials with advantageous electrical, thermal, and mechanical properties for use in thermoelectric devices.

### BRIEF SUMMARY OF THE INVENTION

The present invention is directed to nanostructures. More particularly, the invention provides electrode structures for arrays of nanostructures and methods thereof. Merely by way of example, the invention has been applied to arrays of nanostructures embedded in one or more fill materials with electrode structures for use in thermoelectric devices. However, it would be recognized that the invention has a much broader range of applicability, including but not limited to use in solar power, battery electrodes and/or energy storage, catalysis, and/or light emitting diodes.

According to one embodiment, a thermoelectric device includes nanowires, a contact layer, and a shunt. Each of the nanowires includes a first end and a second end. The contact layer electrically couples the nanowires through at least the first end of each of the nanowires. The shunt is electrically coupled to the contact layer. All of the nanowires are substantially parallel to each other. A first contact resistivity between the first end and the contact layer ranges from 10⁻¹³ Ω-m² to 10⁻⁷ Ω-m². A first work function between the first end and the contact layer is less than 0.8 electron volts. The contact layer is associated with a first thermal resistance ranging from 10⁻² K/W to 10¹⁰ K/W.

According to another embodiment, a thermoelectric device includes nanowires, a first electrode structure, and a second electrode structure. Each of the nanowires includes a first end and a second end opposite to the first end. The first electrode structure includes a first contact layer and a first shunt, the first contact layer electrically coupling the nanowires through at least the first end of each of the nanowires, the first shunt electrically coupled to the first contact layer. The second electrode structure includes a second contact layer and a second shunt, the second contact layer electrically coupling the nanowires through at least the second end of each of the nanowires, the second shunt electrically coupled to the second contact layer. All the nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the second end and the second contact layer ranges from 10⁻¹³ Ω-m² to 10⁻⁷ Ω-m². A second work function between the second end and the second contact layer is less than 0.8 electron volts. The second contact layer is associated with a second thermal resistance ranging from 10⁻² K/W to 10¹⁰ K/W.

According to yet another embodiment, a thermoelectric device includes first nanowires, a first electrode structure, second nanowires different from the first nanowires, and a second electrode structure. Each of the first nanowires includes a first end and a second end opposite to the first end. The first electrode structure includes a first contact layer and a first shunt, the first contact layer electrically coupling the first nanowires through at least the first end of each of the first nanowires, the first shunt electrically coupled to the first contact layer. Each of the second nanowires includes a third end and a fourth end opposite to the third end. The second electrode structure includes a second contact layer and a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. The second end is electrically coupled to the fourth end.

According to yet another embodiment, a thermoelectric device includes first nanowires associated with a first side of a substrate, a first electrode structure, second nanowires associated with a second side of the substrate, and a second electrode structure. Each of the first nanowires includes a first end and a second end opposite to the first end. The first electrode structure includes a first contact layer and a first shunt, the first contact layer electrically coupling the first nanowires through at least the first end of each of the first nanowires, the first shunt electrically coupled to the first contact layer. The second nanowires being different from the first nanowires. The second side being opposite the first side. Each of the second nanowires includes a third end and a fourth end opposite to the third end. The second electrode structure includes a second contact layer and a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W.

According to yet another embodiment, a method for making a thermoelectric device includes forming nanowires, depositing a contact layer, and forming a shunt. Each of the nanowires includes a first end and a second end. The contact layer electrically couples the nanowires through at least the first end of each of the nanowires. The shunt is electrically coupled to the contact layer. All of the nanowires are substantially parallel to each other. A first contact resistivity between the first end and the contact layer ranges from 10⁻¹³ Ω-m² to 10⁻⁷ Ω-m². A first work function between the first end and the contact layer is less than 0.8 electron volts. The contact layer is associated with a first thermal resistance ranging from 10⁻² K/W to 10¹⁰ K/W.

According to yet another embodiment, a method for making a thermoelectric device includes forming nanowires, forming a first electrode structure, and forming a second electrode structure. Each of the nanowires includes a first end and a second end opposite to the first end. Forming the first electrode structure includes depositing a first contact layer and forming a first shunt, the first contact layer electrically coupling the nanowires through at least the first end of each of the nanowires, the first shunt electrically coupled to the first contact layer. Forming the second electrode structure includes depositing a second contact layer and forming a second shunt, the second contact layer electrically coupling the nanowires through at least the second end of each of the nanowires, the second shunt electrically coupled to the second contact layer. All the nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the second end and the second contact layer ranges from 10⁻¹³ Ω-m² to 10⁻⁷ Ω-m². A second work function between the second end and the second contact layer is less than 0.8 electron volts. The second contact layer is associated with a second thermal resistance ranging from 10⁻² K/W to 10¹⁰ K/W.

In yet another embodiment, a method for making a thermoelectric device includes forming first nanowires, forming a first electrode structure, forming second nanowires different from the first nanowires, forming a second electrode structure, and electrically coupling the second end to the fourth end. Each of the first nanowires includes a first end and a second end opposite to the first end. Forming the first electrode structure includes depositing a first contact layer and forming a first shunt, the first contact layer electrically coupling the first nanowires through at least the first end of each of the first nanowires, the first shunt electrically coupled to the first contact layer. Each of the second nanowires includes a third end and a fourth end opposite to the third end. Forming the second electrode structure includes depositing a second contact layer and forming a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W.

According to yet another embodiment, a method for making a thermoelectric device includes forming first nanowires associated with a first side of a substrate, forming a first electrode structure, forming second wires associated with a second side of the substrate, and forming a second electrode structure. Each of the first nanowires includes a first end and a second end opposite to the first end. Forming the first electrode structure includes depositing a first contact layer and forming a first shunt, the first contact layer electrically coupling the first nanowires through at least the first end of each of the first nanowires, the first shunt electrically coupled to the first contact layer. The second nanowires are different from the first nanowires. The second side is opposite the first side. Each of the second nanowires includes a third end and a fourth end opposite to the third end. Forming the second electrode structure includes depositing a second contact layer and forming a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. For example, the method is implemented according to at least FIG. 19.

Depending upon the embodiment, one or more of these benefits may be achieved. These benefits and various additional objects, features, and advantages of the present invention can be fully appreciated with reference to the detailed description and accompanying drawings that follow.

### BRIEF DESCRIPTION OF THE DRAWINGS

FIG. 1 is a simplified diagram showing an array of nanowires with an electrode structure according to one embodiment of the present invention.

FIG. 2 is a simplified diagram showing an array of nanowires with an electrode structure according to another embodiment of the present invention.

FIG. 3 is a simplified diagram showing an array of nanowires with an electrode structure according to another embodiment of the present invention.

FIG. 4 is a simplified diagram showing an array of nanowires with an electrode structure according to another embodiment of the present invention.

FIG. 5 is a simplified diagram showing an array of nanowires with an electrode structure according to another embodiment of the present invention.

FIG. 6 is a simplified diagram showing an array of nanowires with an electrode structure according to another embodiment of the present invention.

FIG. 7A is a simplified diagram showing a thermoelectric device leg according to one embodiment of the present invention.

FIG. 7B is a simplified diagram showing a portion of a thermoelectric device according to one embodiment of the present invention.

FIG. 8A is a simplified diagram showing a thermoelectric device leg according to another embodiment of the present invention.

FIG. 8B is a simplified diagram showing a portion of a thermoelectric device according to another embodiment of the present invention.

FIG. 9A is a simplified diagram showing a thermoelectric device leg according to another embodiment of the present invention.

FIG. 9B is a simplified diagram showing a portion of a thermoelectric device according to another embodiment of the present invention.

FIG. 10 is a simplified diagram showing a method for forming electrode structures on arrays of nanostructures according to one embodiment of the present invention.

FIG. 11 is a simplified diagram showing the process for forming nanostructure arrays in one or more substrates as part of the method for forming electrode structures on arrays of nanostructures according to one embodiment of the present invention.

FIG. 12A is a simplified diagram showing a substrate used for the process for providing a substrate as part of the method for forming electrode structures on arrays of nanostructures according to one embodiment of the present invention.

FIG. 12B is a simplified diagram showing an array of nanostructures in a substrate as formed by the process as shown in FIG. 11 as part of the method for forming electrode structures on arrays of nanostructures according to one embodiment of the present invention.

FIG. 13 is a simplified diagram showing the process for filling the array of nanostructures in a substrate as part of the method for forming electrode structures on arrays of nanostructures according to one embodiment of the present invention.

FIG. 14 is a simplified diagram of a filled array of nanostructures in a substrate as formed by the process of FIG. 13 as part of the method for forming electrode structures on arrays of nanostructures according to one embodiment of the present invention.

FIG. 15 is a simplified diagram showing a process for forming one or more contact layers on the nanostructure arrays as part of the method for forming electrode structures on arrays of nanostructures according to one embodiment of the present invention.

FIG. 16A is a simplified diagram of a filled and planarized array of nanostructures in a substrate as formed by the planarization process as part of the method for forming electrode structures on arrays of nanostructures according to one embodiment of the present invention.

FIG. 16B is a simplified diagram of a filled and planarized array of nanostructures with exposed segments as formed by the process for exposing nanostructure segments as part of the method for forming electrode structures on arrays of nanostructures according to one embodiment of the present invention.

FIG. 17A is a scanning electron microscope image showing a surface of an array of nanostructures before exposure of the exposed segments of the array of nanostructures as part of the method for forming electrode structures on arrays of nanostructures according to one embodiment of the present invention.

FIG. 17B is a scanning electron microscope image showing a surface of an array of nanostructures after exposure of the exposed segments of the array of nanostructures as part of the method for forming electrode structures on arrays of nanostructures according to one embodiment of the present invention.

FIG. 18 is a simplified diagram showing a method for forming electrode structures on arrays of nanostructures according to another embodiment of the present invention.

FIG. 19 is a simplified diagram showing a method for forming electrode structures on arrays of nanostructures according to another embodiment of the present invention.

FIG. 20 is a simplified diagram of a substrate with arrays of nanowires on opposing sides of a substrate as formed by the process for forming nanostructure arrays in opposing sides of a substrate as part of the method for forming electrode structures on arrays of nanostructures according to one embodiment of the present invention.

FIGS. 21A and 21B are simplified diagrams showing a plot of TEG power versus device size for different electrode structure thicknesses for a fixed thermoelectric cross-sectional area.

FIGS. 22A and 22B are simplified diagrams showing a plot of TEG power versus device size for different electrode structure thicknesses at a fixed cross-sectional area.

### DETAILED DESCRIPTION OF THE INVENTION

The present invention is directed to nanostructures. More particularly, the invention provides electrode structures for arrays of nanostructures and methods thereof. Merely by way of example, the invention has been applied to arrays of nanostructures embedded in one or more fill materials with electrode structures for use in thermoelectric devices. However, it would be recognized that the invention has a much broader range of applicability, including but not limited to use in solar power, battery electrodes and/or energy storage, catalysis, and/or light emitting diodes.

In general, the usefulness of a thermoelectric material depends upon the physical geometry of the material. For example, the larger the surface area of the thermoelectric material that is presented on the hot and cold sides of a thermoelectric device, the greater the ability of the thermoelectric device to support heat and/or energy transfer through an increase in power density. In another example, a suitable minimum distance (i.e., the length of the thermoelectric nanostructure) between the hot and cold sides of the thermoelectric material help to better support a higher thermal gradient across the thermoelectric device. This in turn may increase the ability to support heat and/or energy transfer by increasing power density.

One type of thermoelectric nanostructure is an array of nanowires with suitable thermoelectric properties. Nanowires can have advantageous thermoelectric properties, but to date, conventional nanowires and nanowire arrays have been limited in their technological applicability due to the relatively small sizes of arrays and the short lengths of fabricated nanowires. Another type of nanostructure with thermoelectric applicability is nanoholes or nanomeshes. Nanohole or nanomesh arrays also have limited applicability due to the small volumes into which these nanostructures can be created or synthesized. For example, conventional nanostructures with lengths shorter than 100 μm have limited applicability in power generation and/or heat pumping, and conventional nanostructures with lengths shorter than 10 μm have even less applicability because the ability to maintain or establish a temperature gradient using available heat exchange technology across these short lengths is greatly diminished. Furthermore, in another example, arrays smaller than the wafer dimensions of 4, 6, 8, and 12 inches are commercially limited.

The development of large arrays of very long nanostructures formed using semiconductor materials, such as silicon, can be useful in the formation of thermoelectric devices. For example, nanostructure-based thermoelectric materials can have advantageous thermoelectric properties, but to date have not been effectively incorporated into working devices. In another example, silicon nanostructures that have a low thermal conductivity, and formed within a semiconductor substrate, can be utilized to form a plurality of thermoelectric elements for making a thermoelectric device. In yet another example, silicon nanowires can be formed within the predetermined area of the semiconductor substrate and utilized as the n- or p-type legs or both in an assembled thermoelectric device.

However, there are often many difficulties in forming and utilizing arrays of nanostructures. For example, the nanostructures are often fragile and can be easily bent or broken. In another example, the nanostructures cannot be directly applied to high temperature surfaces due to diffusion and/or corrosion. In yet another example, the nanostructures cannot be protruding into and exposed to harsh environments. In yet another example, the nanostructures need a support material to form reliable planar metallic contacts required for thermoelectric applications. In yet another example, the nanostructures need suitable electrode structures for their practical use in thermoelectric and other devices.

More specifically, the nanostructures need electrode structures that satisfy complex and possibly competing requirements according to certain embodiments. For example, the electrode structures should possess low contact resistance with the nanostructures themselves. In another example, the electrode structures should possess a low work function at the nanostructure boundaries. In yet another example, the electrode structures should provide good electrical conductivity between ends of the nanostructures within a same leg of a thermoelectric device. In yet another example, the electrode structures should provide interconnections between different legs of thermoelectric devices that have low resistance. In yet another example, the electrode structures should possess a high thermal conductivity and/or should have low thermal resistance. In yet another example, the electrode structures should survive the high temperatures to which the thermoelectric devices may be exposed. Unfortunately, it is difficult to find a single material with ideal physical and chemical properties for use in thermoelectric devices due to combinations of the desired temperature ranges, geometries, sizes, and electrical and thermal properties. Consequently, electrode structures with multiple cooperating materials are useful in achieving the desired goals according to some embodiments.

According to certain embodiments, if multiple materials are used for the electrode structures, additional physical, electrical, and chemical concerns arise. For example, there should be good bonding and/or adhesion at the interface point(s) between the multiple materials. In another example, there should be low thermal expansion mismatch between the multiple materials. In yet another example, there should be limited inter-material diffusion between the multiple materials. Consequently, arrays of nanostructures would benefit from carefully formed electrode structures according to some embodiments.

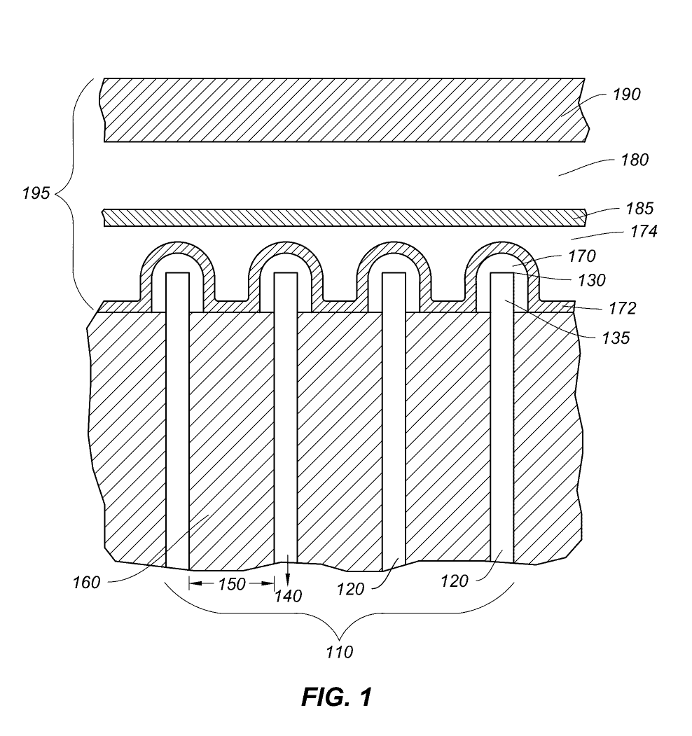

FIG. 1 is a simplified diagram showing an array of nanowires with an electrode structure according to one embodiment of the present invention. This diagram is merely an example, which should not unduly limit the scope of the claims. One of ordinary skill in the art would recognize many variations, alternatives, and modifications. In FIG. 1, an array of nanowires 110 is formed in a block of semiconductor material (e.g., a semiconductor substrate). In one example, the semiconductor substrate is an entire wafer. In another example, the semiconductor substrate is a 4-inch wafer. In yet another example, the semiconductor substrate is a panel larger than a 4-inch wafer. In another example, the semiconductor substrate is a 6-inch wafer. In another example, the semiconductor substrate is an 8-inch wafer. In another example, the semiconductor substrate is a 12-inch wafer. In yet another example, the semiconductor substrate is a panel larger than a 12-inch wafer. In yet another example, the semiconductor substrate is in a shape other than that of a wafer. In yet another example, the semiconductor substrate is single-crystalline. In yet another example, the semiconductor substrate is poly-crystalline. In yet another example, the semiconductor substrate includes silicon.

In some embodiments, the semiconductor substrate is functionalized. For example, the semiconductor substrate is doped to form an n-type semiconductor. In another example, the semiconductor substrate is doped to form a p-type semiconductor. In yet another example, the semiconductor substrate is doped using Group III and/or Group V elements. In yet another example, the semiconductor substrate is functionalized to control the electrical and/or thermal properties of the semiconductor substrate. In yet another example, the semiconductor substrate includes silicon doped with boron and/or phosphorous. In yet another example, the semiconductor substrate is doped to adjust the resistivity of the semiconductor substrate to between approximately 0.00001 Ω-m and 3000 Ω-m. In yet another example, the semiconductor substrate is functionalized to provide the array of nanowires 110 with a thermal conductivity between 0.1 W/(m·K) (i.e., Watts per meter per degree Kelvin) and 500 W/(m·K).

In other embodiments, the array of nanowires 110 is formed in the semiconductor substrate. For example, the array of nanowires 110 is formed in substantially all of the semiconductor substrate. In another example, the array of nanowires 110 includes a plurality of nanowires 120. In yet another example, each of the plurality of nanowires 120 has an end 130. In yet another example, the ends 130 of the plurality of nanowires 120 collectively form an array area. In yet another example, the array area is 0.01 mm by 0.01 mm. In yet another example, the array area is 0.1 mm by 0.1 mm. In yet another example, the array area is 450 mm in diameter. In yet another example, a distance between each of the ends 130 of the plurality of nanowires 120 and opposite ends 140 of each of the plurality of nanowires 120 is at least 200 μm. In yet another example, the distance between each of the ends 130 of the plurality of nanowires 120 and the opposite ends 140 of each of the plurality of nanowires 120 is at least 300 μm. In yet another example, the distance between each of the ends 130 of the plurality of nanowires 120 and the opposite ends 140 of each of the plurality of nanowires 120 is at least 400 μm. In yet another example, the distance between each of the ends 130 of the plurality of nanowires 120 and the opposite ends 140 of each of the plurality of nanowires 120 is at least 500 μm. In yet another example, the distance between each of the ends 130 of the plurality of nanowires 120 and the opposite ends 140 of each of the plurality of nanowires 120 is at least 525 μm.

In yet another example, all the nanowires of the plurality of nanowires 120 are substantially parallel to each other. In yet another example, the plurality of nanowires 120 is formed substantially vertically in the semiconductor substrate. In yet another example, the plurality of nanowires 120 are oriented substantially perpendicular to the array area. In yet another example, each of the plurality of nanowires 120 has a roughened surface. In yet another example, each of the plurality of nanowires 120 includes a substantially uniform cross-sectional area with a large ratio of length to cross-sectional area. In yet another example, the cross-sectional area of each of the plurality of nanowires 120 is substantially circular. In yet another example, the cross-sectional area of each of the plurality of nanowires 120 is between 1 nm to 250 nm across.

In yet other embodiments, the plurality of nanowires 120 have respective spacings 150 between them. For example, each of the respective spacings 150 is between 25 nm to 1000 nm across. In another example, the respective spacings 150 are substantially filled with one or more fill materials 160. In yet another example, the one or more fill materials 160 form a matrix. In yet another example, the matrix is porous. In yet another example, the one or more fill materials 160 have a low thermal conductivity. In yet another example, the thermal conductivity is between 0.0001 W/(m·K) and 50 W/(m·K). In yet another example, thermal conductivity is less than 1 W/(m·K). In yet another example, the one or more fill materials 160 provide added mechanical stability to the plurality of nanowires 120. In yet another example, the one or more fill materials 160 are able to withstand temperatures in excess of 350° C. for extended periods of device operation. In yet another example, the one or more fill materials 160 are able to withstand temperatures in excess of 550° C. for extended periods of device operation. In yet another example, the one or more fill materials 160 are able to withstand temperatures in excess of 650° C. for extended periods of device operation. In yet another example, the one or more fill materials 160 are able to withstand temperatures in excess of 750° C. In yet another example, the one or more fill materials 160 are able to withstand temperatures in excess of 800° C. In yet another example, the one or more fill materials 160 have a low linear coefficient of thermal expansion. In yet another example, the linear coefficient of thermal expansion is between 0.01 μm/m·K and 30 μm/m·K. In yet another example, the one or more fill materials 160 are able to be planarized. In yet another example, the one or more fill materials 160 are able to be polished. In yet another example, the one or more fill materials 160 provide a support base for additional material overlying thereon. In yet another example, the one or more fill materials 160 are conductive. In yet another example, the one or more fill materials 160 support the formation of good electrical contacts with the plurality of nanowires 120. In yet another example, the one or more fill materials 160 support the formation of good thermal contacts with the plurality of nanowires 120.

In yet other embodiments, the one or more fill materials 160 each include at least one selected from a group consisting of photoresist, spin-on glass, spin-on dopant, aerogel, xerogel, and oxide, and the like. For example, the photoresist includes long UV wavelength G-line (e.g., approximately 436 nm) photoresist. In another example, the photoresist has negative photoresist characteristics. In yet another example, the photoresist exhibits good adhesion to various substrate materials, including Si, GaAs, InP, and glass. In yet another example, the photoresist exhibits good adhesion to various metals, including Au, Cu, and Al. In yet another example, the spin on glass has a high dielectric constant. In yet another example, the spin-on dopant includes n-type and/or p-type dopants. In yet another example, the spin-on dopant is applied regionally with different dopants in different areas of the array of nanowires 110. In yet another example, the spin-on dopant includes boron and/or phosphorous and the like. In yet another example, the spin-on glass includes one or more spin-on dopants. In yet another example, the aerogel is derived from silica gel characterized by an extremely low thermal conductivity of about 0.1 W/(m·K) and lower. In yet another example, the one or more fill materials include long chains of one or more oxides. In yet another example, the one or more fill materials includes at least one selected from a group consisting of Al₂O₃, FeO, FeO₂, Fe₂O₃, TiO, TiO₂, ZrO₂, ZnO, HfO₂, CrO, Ta₂O₅, SiN, TiN, BN, SiO₂, AlN, CN, and/or the like.

According to some embodiments, the one or more fill materials 160 do not completely fill the respective spacings 150 between the plurality of nanowires 120. In one example, the ends 130 extend beyond the one or more fill materials 160 to form protruding segments 135. In yet another example, the ends 130, the opposite ends 140, and the one or more fill materials 160 define multiple regions along the length of each of the plurality of nanowires 120. In yet another example, a region that extends from the ends 130 to a surface of the one or more fill materials 160 closest to the ends 130 corresponds to the protruding segments 135.

According to some embodiments, the array of nanowires 110 embedded in the one or more fill materials 160 has useful characteristics. For example, the embedded array of nanowires 110 is well aligned. In another example, the embedded array of nanowires 110 survives high temperature gradients without breaking. In yet another example, the embedded array of nanowires 110 survives high temperature gradients without bending or breaking of the plurality of nanowires 120. In yet another example, the enhanced mechanical strength of the embedded array of nanowires 110 allows one or more surface polishing and/or planarization processes to be carried out on one or more surfaces of the embedded array of nanowires 110. In yet another example, the enhanced mechanical strength of the embedded array of nanowires 110 provides support for handling, machining, and/or manufacturing processes to be carried out on the embedded array of nanowires 110. In yet another example, the protruding segments 135 support the formation of one or more electrical and/or one or more thermal contacts with the array of nanowires 110.

According to some embodiments, an electrode structure 195 is formed on the array of nanowires 110. For example, each of the protruding segments 135 is partially or completely covered with respective semiconductor contact materials 170. In yet another example, the semiconductor contact materials 170 forms a conformal coating on the respective protruding segment 135. In yet another example, the semiconductor contact materials 170 forms a layer. In some embodiments, the semiconductor contact materials 170 each include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like.

In yet another example, the semiconductor contact materials 170 form one or more electric contacts with the ends 130 of the plurality of nanowires 120. In yet another example, the semiconductor contact materials 170 form one or more ohmic contacts with the ends 130 of the plurality of nanowires 120. In yet another example, the semiconductor contact materials 170 are configured to form one or more good thermal contacts with one or more surfaces for establishing one or more thermal paths through the one or more pluralities of the nanowire 120 while limiting thermal leakage in the one or more fill materials 160. In yet another example, the semiconductor contact materials 170 have a low contact resistitivity with the protruding segments 135. In yet another example, the contact resistivity is less than 10⁻⁷ Ω-m². In yet another example, the contact resistivity is between 10⁻¹³ Ω-m² and 10⁻⁷ Ω-m². In yet another example, the semiconductor contact materials 170 have a low work function between the semiconductor contact materials 170 and the protruding segments 135. In yet another example, the work function is less than 0.8 electron volts. In yet another example, the semiconductor contact materials 170 have a thermal expansion that is approximately the same as the plurality of nanowires 120. In yet another example the semiconductor contact materials 170 have a thermal expansion between 0.4 μm/(m·K) and 25 μm/(m·K).

According to some embodiments, a contact layer 174 is formed to provide electrical connection between each of the protruding segments 135 in the array of nanowires 110. For example, the array of nanowires forms a portion of a leg of a thermoelectric device. In another example, the contact layer 174 has an electrical conductivity of between 10⁶ S/m and 10⁸ S/m. In yet another example, the contact layer 174 has a high thermal conductivity. In yet another example, the thermal conductivity is greater than 1 W/(m·K). In yet another example, the contact layer has a low thermal resistance. In yet another example, the thermal resistance is between 10⁻² K/W and 10¹⁰ K/W. In yet another example, the contact layer 174 includes one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the contact layer 174 is approximately 50 nm in thickness. In yet another example, the contact layer 174 has a thickness between 1 nm and 100,000 nm.

According to some embodiments, the contact layer 174 is attached to the semiconductor contact materials 170 using one or more bonding materials 172. In one example, the bonding materials 172 form a layer. In another example, the bonding materials 172 include solder. In yet another example, the solder includes at least one material from a group consisting of Ag, Cu, Sn, Pb, Au, In, Cd, Zn, Bi, and the like. In yet another example, the bonding materials 172 include a brazing material including at least one material from a group consisting of Ga, Ge, Ag, Au, Pt, and the like. In yet another example, the bonding materials 172 include silver-based metal adhesive. In yet another example, the bonding materials 172 have a thickness of 100 nm or less. In yet another example, the bonding materials 172 have a thickness of 1000 nm or less. In yet another example the bonding materials 172 have a thermal expansion between 0.4 μm/(m·K) and 25 μm/(m·K). In yet another example, the bonding materials 172 have a low thermal resistance. In yet another example, the thermal resistance is between 10⁻² K/W and 10¹⁰ K/W. In yet another example, the bonding materials 172 have a low sheet resistance. In yet another example, the sheet resistance is between 10⁻¹⁰Ω/□ and 10 Ω/□ (ohms per square).

According to some embodiments, a shunt 180 is formed to provide electrical connection between the contact layer 174 and other devices in a thermoelectric device. For example, the other devices include one or more contact layers of other legs of the thermoelectric device. In another example, the shunt 180 forms a layer. In yet another example, the shunt 180 has a low sheet resistance. In yet another example, the sheet resistance is between 10⁻¹⁰Ω/□ and 10Ω/□. In yet another example, the shunt 180 includes one or more conductive materials. In yet another example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, graphite, steel, an alloy of nickel and iron, an alloy of cobalt, chromium, nickel, iron, molybdenum, and manganese, and the like. In yet another example, the alloy of nickel and iron is Alloy 42, which includes approximately 42% nickel, approximately 57% iron, and trace amounts of carbon, manganese, phosphorous, sulfur, silicon, chromium, aluminum, and/or cobalt by weight. In yet another example, the alloy of cobalt, chromium, nickel, iron, molybdenum, and manganese is Egiloy, which includes approximately 39-41% cobalt, approximately 19-21% chromium, approximately 14-16% nickel, approximately 11.3-20.5% iron, approximately 6-8% molybdenum, and/or approximately 1.5-2.5% manganese by weight. In yet another example, the shunt 180 has a thickness between 1 nm and 100,000 nm.

According to some embodiments, the shunt 180 is attached to the contact layer 170 using one or more bonding materials 185. In one example, the bonding materials 185 form a layer. In another example, the bonding materials 185 include solder. In yet another example, the solder includes at least one material from the group consisting of Ag, Cu, Sn, Pb, Au, In, Cd, Zn, Bi, and the like. In yet another example, the bonding materials 185 include a brazing material including at least one material from a group consisting of Ga, Ge, Si, Ag, Au, Pt, and the like. In yet another example, the bonding materials 185 include silver-based metal adhesive. In yet another example, the bonding materials 185 have a thickness of 100 nm or less. In yet another example, the bonding materials 185 have a thickness of 1000 nm or less. In yet another example the bonding materials 185 have a thermal expansion between 0.4 μm/(m·K) and 25 μm/(m·K). In yet another example, the bonding materials 185 have a low thermal resistance. In yet another example, the thermal resistance is between 10⁻²K/W and 10¹⁰ K/W. In yet another example, the bonding materials 185 have a low sheet resistance. In yet another example, the sheet resistance is between 10⁻¹⁰Ω/□ and 10 Ω/□.

According to some embodiments, an insulating layer 190 protects the shunt 180. For example, the insulating layer 190 provides electrical insulation to the shunt 180. In another example, the insulating layer 190 reduces the likelihood that the shunt 180 will be shorted against other conductive surfaces. In yet another example, the insulating layer 190 has a high electrical resistance of at least 1 MΩ. In yet another example, the insulating layer 190 has a thermal conductivity of at least 2 W/(m·K) (i.e., Watts per meter per degree Kelvin). In yet another example, the insulating layer 190 has a thickness of 100 nm or less. In yet another example, the insulating layer 190 includes one or more materials selected from a group consisting of SiO₂, Si₃N₄, SiN, Al₂O₃, and the like. In yet another example, the insulating layer 190 is attached to the shunt 180. In yet another example, the insulating layer 190 is part of a heat exchanger in which the thermoelectric device is used.

According to some embodiments, each of the layers selected from a group consisting of semiconductor contact materials 170, bonding materials 172, contact layer 172, bonding materials 185, shunt 180, and insulating layer 190 have suitable material properties for use in a thermoelectric device. For example, these layers collectively form an electrode structure 195 suitable for an end of a leg in a thermoelectric device. In another example, the electrode structure 195 has an overall thickness that ranges from tens of microns to over 10 cm. In yet another example, the electrode structure 195 is optimized based on desired heat exchanger conditions, target surface temperatures, and/or nanowire properties. In yet another example, the electrode structure 195 is optimized to for maximum thermoelectric generator (TEG) power.

In yet another example, each of the layers has good adhesion to the materials in the adjacent layers of the electrode structure 195. In yet another example, there is low variation in the linear coefficient of thermal expansion between adjacent layers. In yet another example, each of the layers has a linear coefficient of thermal expansion between 0.01 μm/(m·K) and 30 μm/(m·K).

In yet another example, a thermal conductivity of the electrode structure is between 1 W/(m·K) and 1000 W/(m·K). In yet another example, the electrode structure 195 is able to withstand temperatures in excess of 350° C. for extended periods of device operation. In yet another example, the electrode structure 195 is able to withstand temperatures in excess of 550° C. for extended periods of device operation. In yet another example, the electrode structure 195 is able to withstand temperatures in excess of 650° C. for extended periods of device operation. In yet another example, the electrode structure 195 is able to withstand temperatures in excess of 750° C. In yet another example, the electrode structure 195 is able to withstand temperatures in excess of 800° C.

In yet another example, a diffusion barrier layer is formed between any of the other two layers. In yet another example, any of the layers selected from a group consisting of semiconductor contact materials 170, bonding materials 172, contact layer 172, bonding materials 185, shunt 180 is a diffusion barrier layer.

According to other embodiments, one or more of the layers in the electrode structure 195 selected from a list consisting of semiconductor contact materials 170, bonding materials 172, contact layer 172, bonding materials 185, shunt 180, and insulating layer 190 are optional.

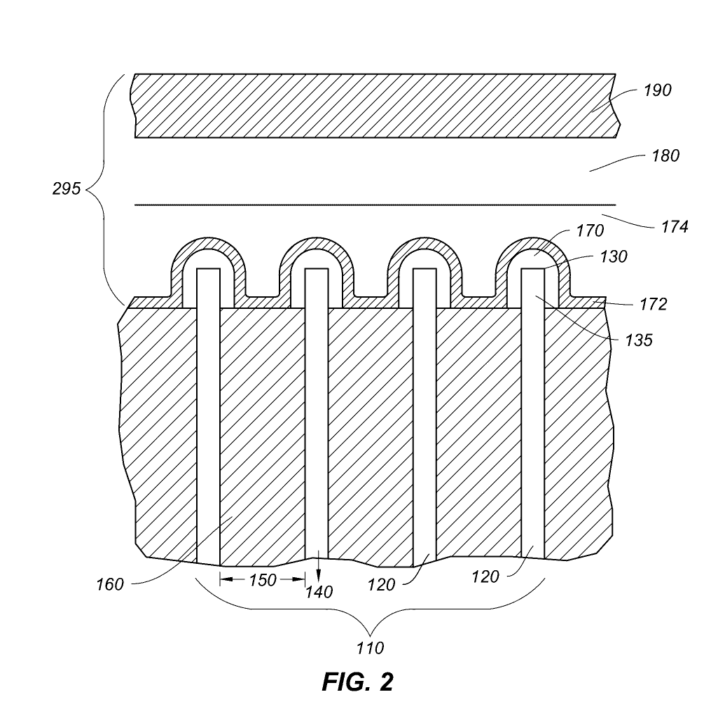

FIG. 2 is a simplified diagram showing an array of nanowires with an electrode structure according to another embodiment of the present invention. This diagram is merely an example, which should not unduly limit the scope of the claims. One of ordinary skill in the art would recognize many variations, alternatives, and modifications. In FIG. 2, the bonding materials 185 are omitted from an electrode structure 295. For example, the electrode structure 295 includes semiconductor contact materials 170, bonding materials 172, contact layer 174, shunt 180, and insulating layer 190. In another example, the insulating layer 190 is omitted.

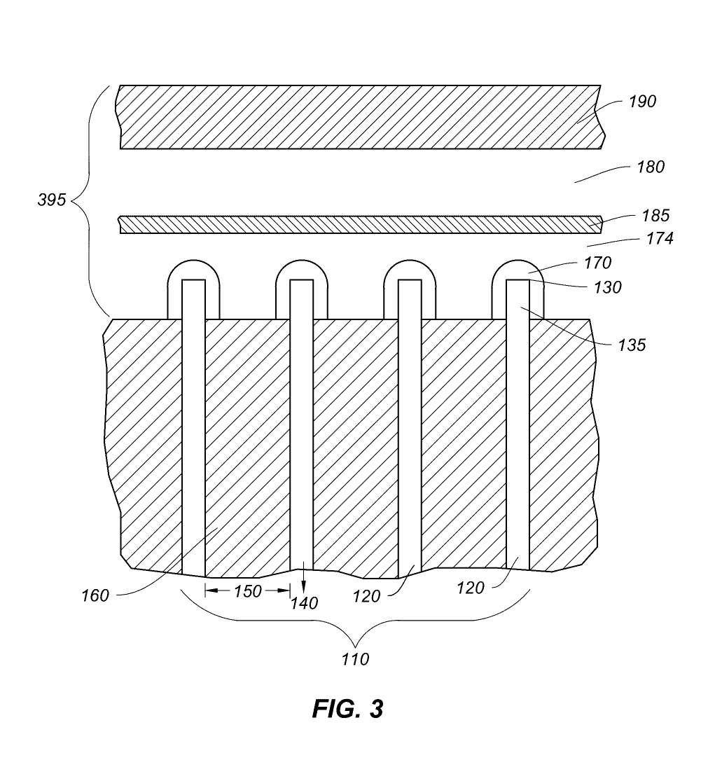

FIG. 3 is a simplified diagram showing an array of nanowires with an electrode structure according to another embodiment of the present invention. This diagram is merely an example, which should not unduly limit the scope of the claims. One of ordinary skill in the art would recognize many variations, alternatives, and modifications. In FIG. 3, the bonding materials 172 are omitted from an electrode structure 395. For example, the electrode structure 295 includes semiconductor contact materials 170, contact layer 174, bonding materials 185, shunt 180, and insulating layer 190. In another example, the insulating layer 190 is omitted.

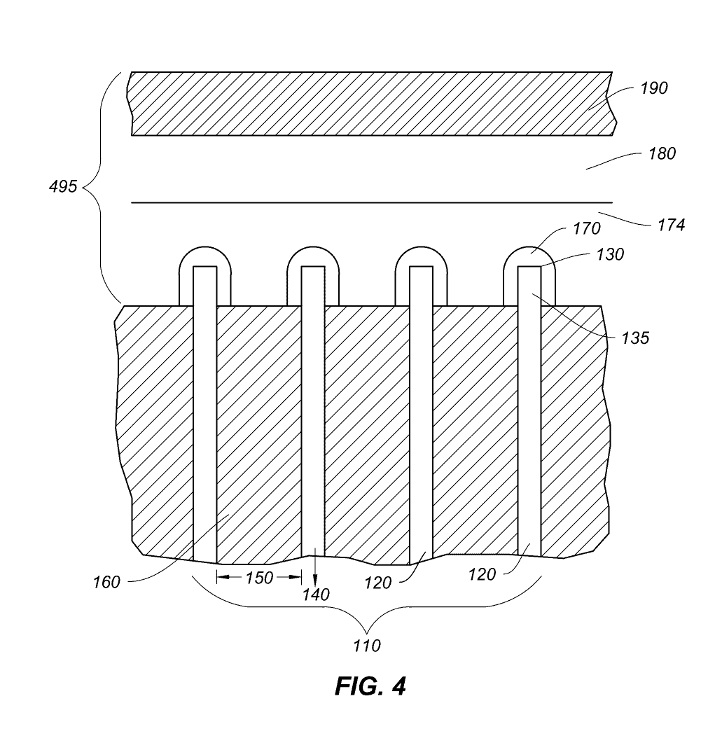

FIG. 4 is a simplified diagram showing an array of nanowires with an electrode structure according to another embodiment of the present invention. This diagram is merely an example, which should not unduly limit the scope of the claims. One of ordinary skill in the art would recognize many variations, alternatives, and modifications. In FIG. 4, the bonding materials 172 and the bonding materials 185 are omitted from an electrode structure 495. For example, the electrode structure 295 includes semiconductor contact materials 170, contact layer 174, shunt 180, and insulating layer 190. In another example, the insulating layer 190 is omitted.

According to yet other embodiments, the semiconductor contact materials 170 and the contact layer 174 are optionally combined.

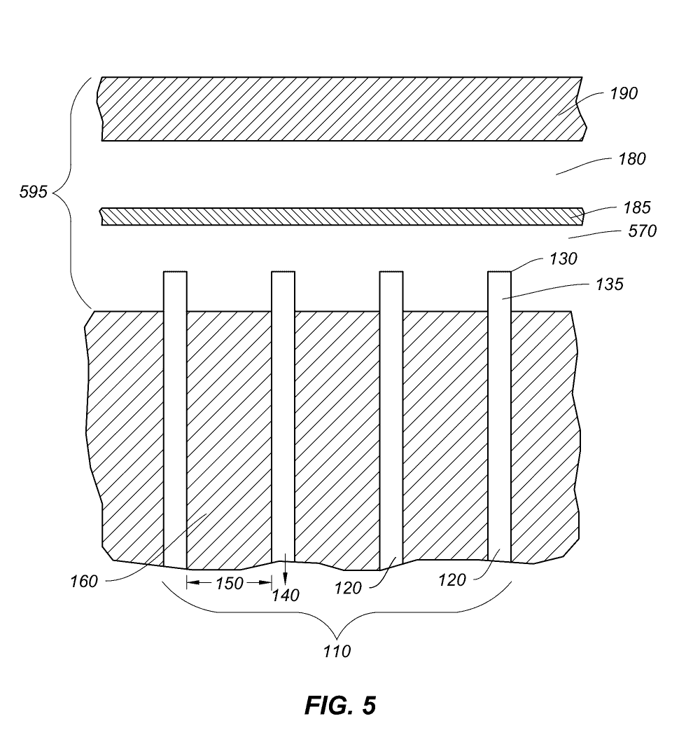

FIG. 5 is a simplified diagram showing an array of nanowires with an electrode structure according to another embodiment of the present invention. This diagram is merely an example, which should not unduly limit the scope of the claims. One of ordinary skill in the art would recognize many variations, alternatives, and modifications. In FIG. 5, the semiconductor contact materials and the contact layer are combined to form a combined contact layer 570 as part of an electrode structure 595. For example, the electrode structure 595 includes combined contact layer 570, bonding materials 185, shunt 180, and insulating layer 190. In another example, each of the protruding segments 135 is covered by the combined contact layer 570. In some embodiments, the combined contact layer 570 includes one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of B, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like.

In yet another example, the combined contact layer 570 forms one or more electric contacts with the ends 130 of the plurality of nanowires 120. In yet another example, the combined contact layer 570 form one or more ohmic contacts with the ends 130 of the plurality of nanowires 120. In yet another example, combined contact layer 570 is configured to form one or more good thermal contacts with one or more surfaces for establishing one or more thermal paths through the one or more pluralities of the nanowire 120 while limiting thermal leakage in the one or more fill materials 160. In yet another example, a contact resistivity between the combined contact layer 570 and the protruding segments is below 10⁻⁸ Ω-m2. In yet another example, the combined contact layer 570 has a low work function between the combined contact layer 570 and the protruding segments 135. In yet another example, the work function is less than 0.8 electron volts. In yet another example, the combined contact layer 570 has a thermal expansion that is approximately the same as the plurality of nanowires 120. In yet another example the combined contact layer 570 has a thermal expansion between 0.4 μm/(m·K) and 25 μm/(m·K). In yet another example, the combined contact layer 570 is approximately 50 nm in thickness. In yet another example, the combined contact layer 570 has a thickness between 1 nm and 100,000 nm. In another example, the insulating layer 190 is omitted.

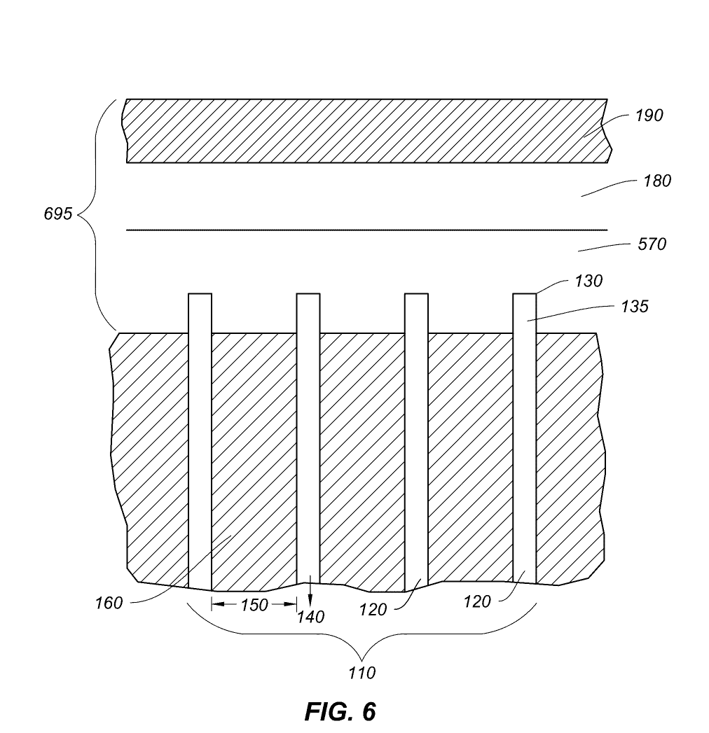

FIG. 6 is a simplified diagram showing an array of nanowires with an electrode structure according to another embodiment of the present invention. This diagram is merely an example, which should not unduly limit the scope of the claims. One of ordinary skill in the art would recognize many variations, alternatives, and modifications. In FIG. 6, the semiconductor contact materials and the contact layer are combined to form the combined contact layer 570 and the bonding materials 185 are omitted as part of an electrode structure 695. For example, the electrode structure 695 includes combined contact layer 570, shunt 180, and insulating layer 190. In another example, the insulating layer 190 is omitted.

As discussed above and further emphasized here, FIGS. 1-6 are merely examples, which should not unduly limit the scope of the claims. One of ordinary skill in the art would recognize many variations, alternatives, and modifications. In some embodiments, nanostructures other than nanowires are formed. In certain embodiments, the nanostructures are completely embedded in the one or more fill materials 160. For example, the respective spacings 150 are completely filled with the one or more fill materials 160. In another example, the ends 130 of the plurality of nanowires are substantially aligned with a surface of the one or more fill materials. In yet another example, the protruding segments 135 are substantially omitted and the semiconductor contact material 172 and/or the combined contact layer 570 make contact with the ends 130. In certain embodiments, the one or more fill materials 160 are omitted.

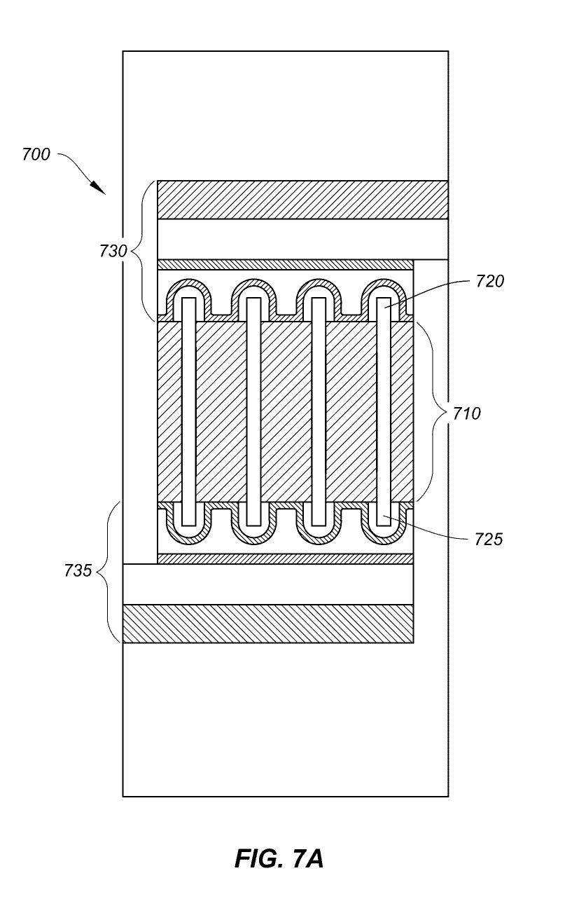

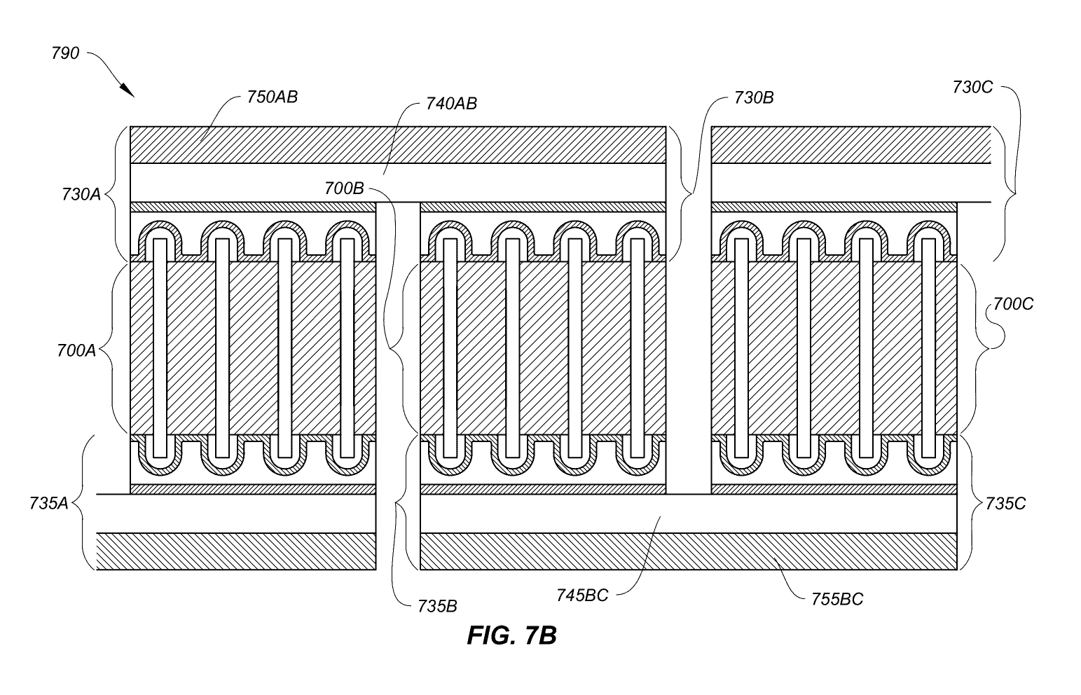

FIG. 7A is a simplified diagram showing a thermoelectric device leg according to one embodiment of the present invention. This diagram is merely an example, which should not unduly limit the scope of the claims. One of ordinary skill in the art would recognize many variations, alternatives, and modifications. In FIG. 7A, the thermoelectric device leg 700 includes an array of nanowires 710. For example, each of the nanowires in the array of nanowires 710 includes a protruding segment 720 and a protruding segment 725. In another example, the protruding segment 720 corresponds to the protruding segment 135 of FIGS. 1-6. In yet another example, the protruding segments 725 corresponds to the protruding segment 135 of FIGS. 1-6. In yet another example, an electrode structure 730 is formed on the protruding segments 720. In yet another example, the electrode structure 730 is the electrode structure 195 and includes semiconductor contact materials, bonding materials, contact layer, bonding materials, shunt, and insulating layer as shown in FIG. 1. In yet another example, an electrode structure 735 is formed on the protruding segments 730. In yet another example, the electrode structure 735 is the electrode structure 195 and includes semiconductor contact materials, bonding materials, contact layer, bonding materials, shunt, and insulating layer as shown in FIG. 1.

FIG. 7B is a simplified diagram showing a portion of a thermoelectric device according to one embodiment of the present invention. This diagram is merely an example, which should not unduly limit the scope of the claims. One of ordinary skill in the art would recognize many variations, alternatives, and modifications. In FIG. 7B, the thermoelectric device 790 includes a plurality of thermoelectric devices legs 700A, 700B, and 700C. For example, each of the thermoelectric device legs 700A, 700B, and 700C is the thermoelectric device leg 700. In another example, the thermoelectric device leg 700A includes an electrode structure 730A. In yet another example, the thermoelectric device leg 700A includes an electrode structure 735A. In yet another example, the thermoelectric device leg 700B includes an electrode structure 730B. In yet another example, the thermoelectric device leg 700B includes an electrode structure 735B. In yet another example, the thermoelectric device leg 700C includes an electrode structure 730C. In yet another example, the thermoelectric device leg 700C includes an electrode structure 735C.

In yet another example, the electrode structure 730A and the electrode structure 730B share a shunt 740AB. In yet another example, the electrode structure 730A and the electrode structure 730B share an insulating layer 750AB. In yet another example, the electrode structure 735B and the electrode structure 735C share a shunt 745BC. In yet another example, the electrode structure 735B and the electrode structure 735C share an insulating layer 755BC.

In yet another example, each of the thermoelectric devices legs 700A, 700B, and 700C are formed from the same semiconductor substrate. In yet another example, each of the thermoelectric devices legs 700A, 700B, and 700C are formed from two or more semiconductor substrates. In yet another example, each of the thermoelectric devices legs 700A, 700B, and 700C have different electrical properties. In yet another example, each of the thermoelectric devices legs 700A, 700B, and 700C have different thermal properties.

As discussed above and further emphasized here, FIGS. 7A and 7B are merely examples, which should not unduly limit the scope of the claims. One of ordinary skill in the art would recognize many variations, alternatives, and modifications. In some embodiments, nanostructures other than nanowires are utilized. In other embodiments, different electrode structures are used for electrode structure 730 and/or electrode structure 735. For example, electrode structure 295 as shown in FIG. 2, electrode structure 395 as shown in FIG. 3, electrode structure 495 as shown in FIG. 4, electrode structure 595 as shown in FIG. 5, and/or electrode structure 695 as shown in FIG. 6 is substituted for one or more of the electrode structures 730, 730A, 730B, 730C, 735, 735A, 735B, and/or 735C. In another example, any combination of different electrode structures are used for each of the electrode structures 730, 730A, 730B, 730C, 735, 735A, 735B, and/or 735C. In certain embodiments one or more substrates is used for the various thermoelectric device legs. For example, each of the thermoelectric device legs 700A, 700B, and 700C are formed in the same substrate. In another example, one or more of the thermoelectric device legs 700A, 700B, and/or 700C are formed in a different substrate. In some embodiments, the insulating layer 750AB and/or the insulating layer 755BC are omitted.

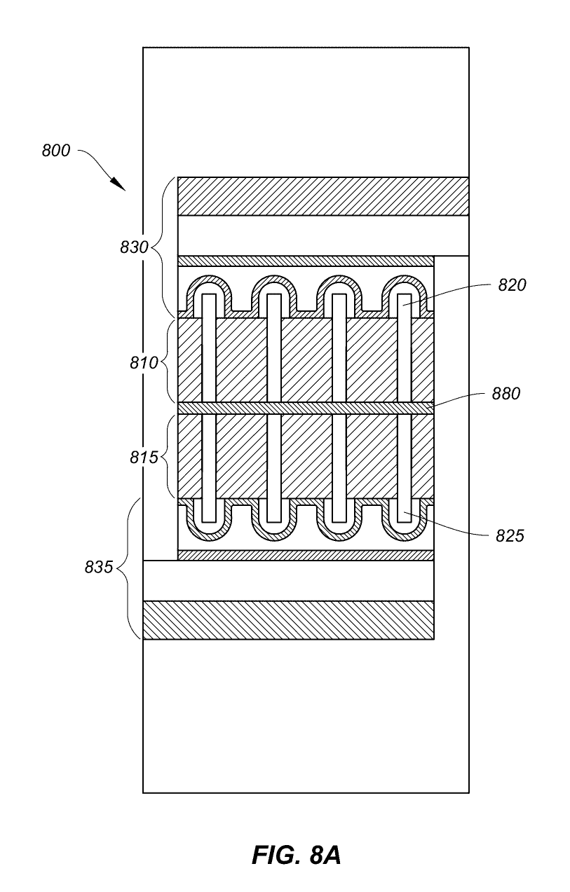

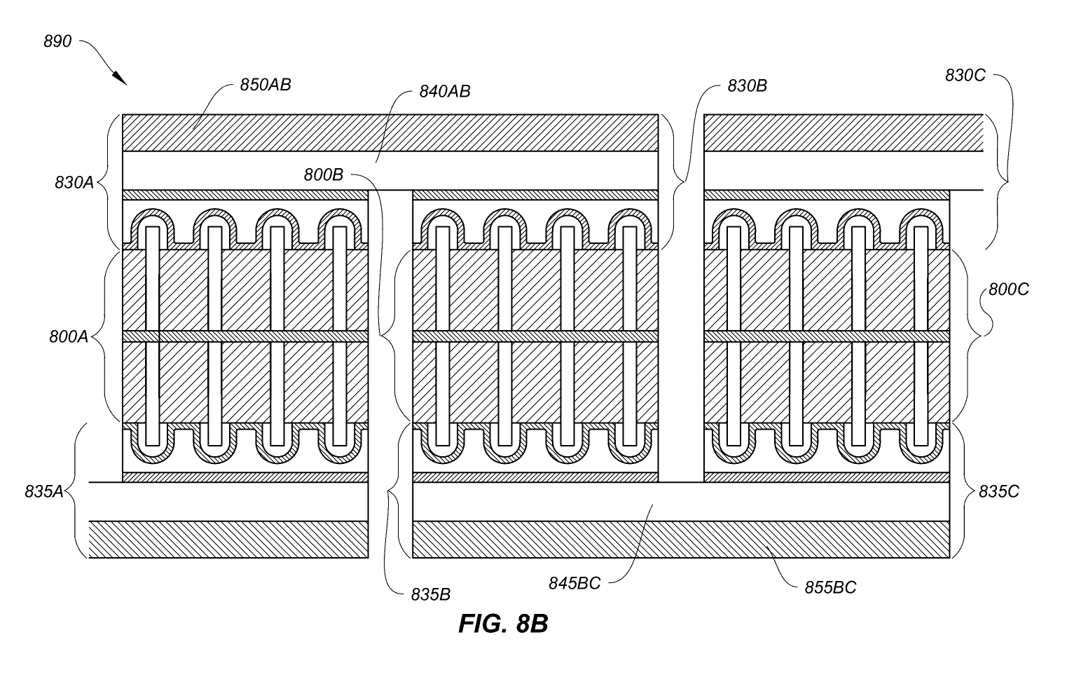

FIG. 8A is a simplified diagram showing a thermoelectric device leg according to another embodiment of the present invention. This diagram is merely an example, which should not unduly limit the scope of the claims. One of ordinary skill in the art would recognize many variations, alternatives, and modifications. In FIG. 8A, the thermoelectric device leg 800 includes a segment of nanowires 810 and a segment of nanowires 815. For example, the segment of nanowires 810 is bonded to the segment of nanowires 815 using segment bonding materials 880. In another example, the segment bonding materials 880 include solder. In yet another example, the solder includes at least one material from the group consisting of Ag, Cu, Sn, Pb, Au, In, Cd, Zn, Bi, and the like. In yet another example, the segment bonding materials 880 include a brazing material including at least one material from a group consisting of Ga, Ge, Si, Ag, Au, Pt, and the like. In yet another example, the segment bonding materials 880 include silver-based metal adhesive. In yet another example, the segment bonding materials 880 have a thickness of 100 nm or less. In yet another example, the segment bonding materials 880 have a thickness of 1000 nm or less. In yet another example the segment bonding materials 880 have a thermal expansion between 0.4 μm/(m·K) and 25 μm/(m·K). In yet another example, the segment bonding materials 880 have a low thermal resistance. In yet another example, the thermal resistance is between 10⁻² K/W and 10¹⁰ K/W. In yet another example, the segment bonding materials 880 have a low sheet resistance. In yet another example, the sheet resistance is between 10⁻¹⁰Ω/□ and 10 Ω/□.

In yet another example, each of the nanowires in the segment of nanowires 810 includes a protruding segment 820. In yet another example, the protruding segment 820 corresponds to the protruding segment 135 of FIGS. 1-6. In yet another example, each of the nanowires in the segment of nanowires 815 includes a protruding segment 825. In yet another example, the protruding segment 825 corresponds to the protruding segment 135 of FIGS. 1-6.

In yet another example, an electrode structure 830 is formed on the protruding segments 820. In yet another example, the electrode structure 830 is the electrode structure 195 and includes semiconductor contact materials, bonding materials, contact layer, bonding materials, shunt, and insulating layer as shown in FIG. 1. In yet another example, an electrode structure 835 is formed on the protruding segments 830. In yet another example, the electrode structure 835 is the electrode structure 195 and includes semiconductor contact materials, bonding materials, contact layer, bonding materials, shunt, and insulating layer as shown in FIG. 1.

FIG. 8B is a simplified diagram showing a portion of a thermoelectric device according to another embodiment of the present invention. This diagram is merely an example, which should not unduly limit the scope of the claims. One of ordinary skill in the art would recognize many variations, alternatives, and modifications. In FIG. 8B, the thermoelectric device 890 includes a plurality of thermoelectric devices legs 800A, 800B, and 800C. For example, each of the thermoelectric device legs 800A, 800B, and 800C is the thermoelectric device leg 800. In another example, the thermoelectric device leg 800A includes an electrode structure 830A. In yet another example, the thermoelectric device leg 800A includes an electrode structure 835A. In yet another example, the thermoelectric device leg 800B includes an electrode structure 830B. In yet another example, the thermoelectric device leg 800B includes an electrode structure 835B. In yet another example, the thermoelectric device leg 800C includes an electrode structure 830C. In yet another example, the thermoelectric device leg 800C includes an electrode structure 835C.

In yet another example, the electrode structure 830A and the electrode structure 830B share a shunt 840AB. In yet another example, the electrode structure 830A and the electrode structure 830B share an insulating layer 850AB. In yet another example, the electrode structure 835B and the electrode structure 835C share a shunt 845BC. In yet another example, the electrode structure 835B and the electrode structure 835C share an insulating layer 855BC.

In yet another example, each of the thermoelectric devices legs 800A, 800B, and 800C have different electrical properties. In yet another example, each of the thermoelectric devices legs 800A, 800B, and 800C have different thermal properties.

As discussed above and further emphasized here, FIGS. 8A and 8B are merely examples, which should not unduly limit the scope of the claims. One of ordinary skill in the art would recognize many variations, alternatives, and modifications. In some embodiments, nanostructures other than nanowires are utilized. In other embodiments, different electrode structures are used for electrode structure 830 and/or electrode structure 835. For example, electrode structure 295 as shown in FIG. 2, electrode structure 395 as shown in FIG. 3, electrode structure 495 as shown in FIG. 4, electrode structure 595 as shown in FIG. 5, and/or electrode structure 695 as shown in FIG. 6 is substituted for one or more of the electrode structures 830, 830A, 830B, 830C, 835, 835A, 835B, and/or 835C. In another example, any combination of different electrode structures are used for each of the electrode structures 830, 830A, 830B, 830C, 835, 835A, 835B, and/or 835C. In some embodiments, more than two segments of nanowire arrays are utilized in the thermoelectric device leg. For example, an additional segment of nanowires is bonded between the segment of nanowires 810 and the segment of nanowires 815. In certain embodiments one or more substrates is used for the various thermoelectric device legs. For example, the segment of nanowires 810 and the segment of nanowires 815 are formed in a same substrate. In another example, the segment of nanowires 810 and the segment of nanowires 815 are formed in two different substrates. In yet another example, each of the thermoelectric device legs 800A, 800B, and 800C are formed in the same substrate. In another example, one or more of the thermoelectric device legs 800A, 800B, and/or 800C are formed in a different substrate. In some embodiments, the insulating layer 850AB and/or the insulating layer 855BC are omitted.

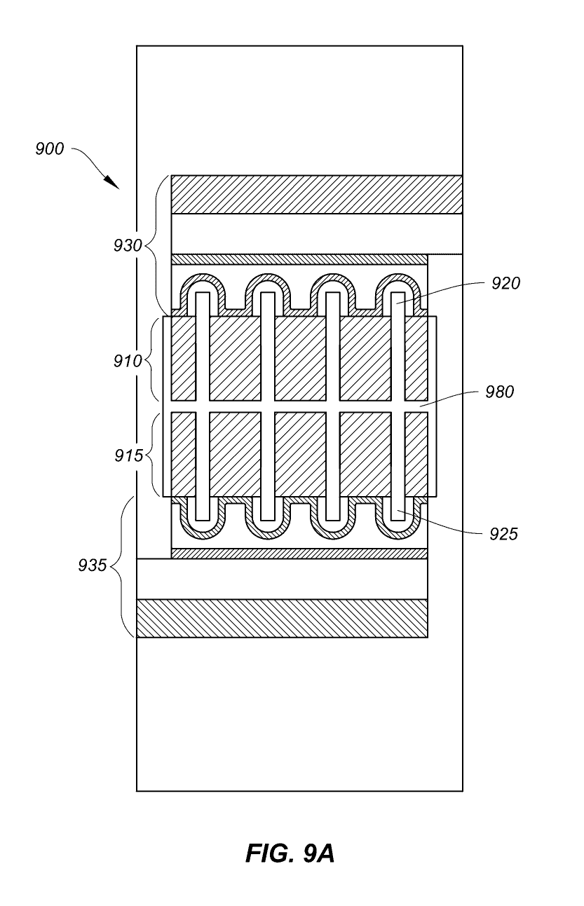

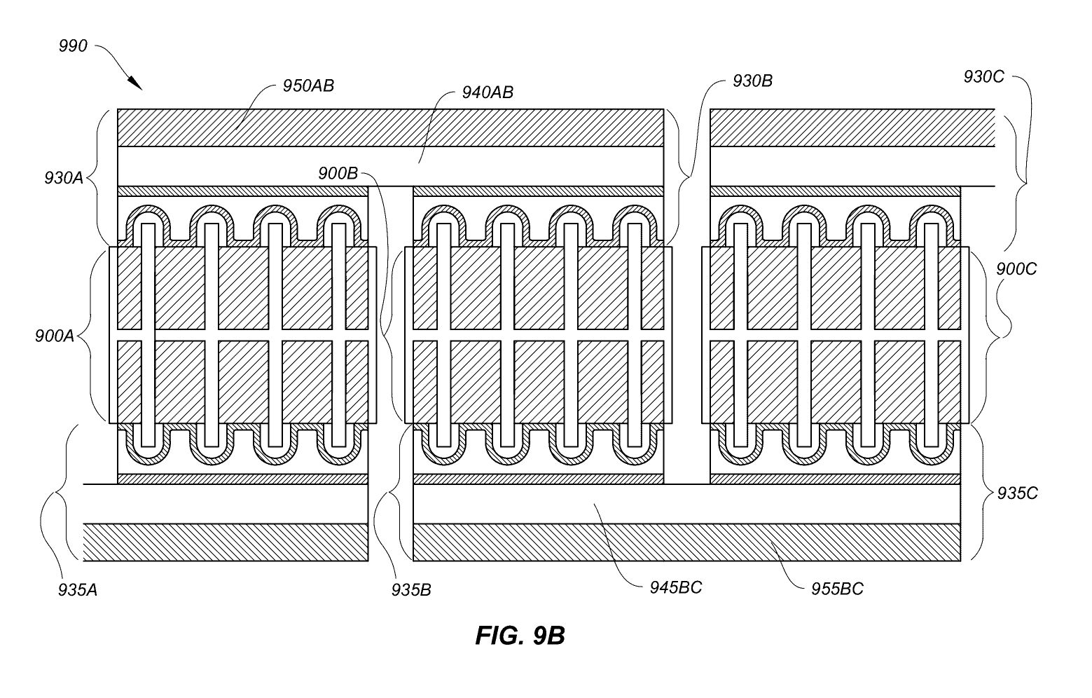

FIG. 9A is a simplified diagram showing a thermoelectric device leg according to another embodiment of the present invention. This diagram is merely an example, which should not unduly limit the scope of the claims. One of ordinary skill in the art would recognize many variations, alternatives, and modifications. In FIG. 9A, the thermoelectric device leg 900 includes an array of nanowires 910 and an array of nanowires 915 formed on opposing sides of a semiconductor substrate 980. For example, each of the nanowires in the array of nanowires 910 includes a protruding segment 920. In another example, each of the nanowires in the array of nanowires 915 includes a protruding segment 925. In another example, the protruding segment 920 corresponds to the protruding segment 135 of FIGS. 1-6. In yet another example, the protruding segments 925 corresponds to the protruding segment 135 of FIGS. 1-6. In yet another example, an electrode structure 930 is formed on the protruding segments 920. In yet another example, the electrode structure 930 is the electrode structure 195 and includes semiconductor contact materials, bonding materials, contact layer, bonding materials, shunt, and insulating layer as shown in FIG. 1. In yet another example, an electrode structure 935 is formed on the protruding segments 930. In yet another example, the electrode structure 935 is the electrode structure 195 and includes semiconductor contact materials, bonding materials, contact layer, bonding materials, shunt, and insulating layer as shown in FIG. 1.

FIG. 9B is a simplified diagram showing a portion of a thermoelectric device according to another embodiment of the present invention. This diagram is merely an example, which should not unduly limit the scope of the claims. One of ordinary skill in the art would recognize many variations, alternatives, and modifications. In FIG. 9B, the thermoelectric device 990 includes a plurality of thermoelectric devices legs 900A, 900B, and 900C. For example, each of the thermoelectric device legs 900A, 900B, and 900C is the thermoelectric device leg 900. In another example, the thermoelectric device leg 900A includes an electrode structure 930A. In yet another example, the thermoelectric device leg 900A includes an electrode structure 935A. In yet another example, the thermoelectric device leg 900B includes an electrode structure 930B. In yet another example, the thermoelectric device leg 900B includes an electrode structure 935B. In yet another example, the thermoelectric device leg 900C includes an electrode structure 930C. In yet another example, the thermoelectric device leg 900C includes an electrode structure 935C.

In yet another example, the electrode structure 930A and the electrode structure 930B share a shunt 940AB. In yet another example, the electrode structure 930A and the electrode structure 930B share an insulating layer 950AB. In yet another example, the electrode structure 935B and the electrode structure 935C share a shunt 945BC. In yet another example, the electrode structure 935B and the electrode structure 935C share an insulating layer 955BC.

In yet another example, each of the thermoelectric devices legs 900A, 900B, and 900C are formed from a same semiconductor substrate. In yet another example, each of the thermoelectric devices legs 900A, 900B, and 900C are formed from two or more semiconductor substrates. In yet another example, each of the thermoelectric devices legs 900A, 900B, and 900C have different electrical properties. In yet another example, each of the thermoelectric devices legs 900A, 900B, and 900C have different thermal properties.

As discussed above and further emphasized here, FIGS. 9A and 9B are merely examples, which should not unduly limit the scope of the claims. One of ordinary skill in the art would recognize many variations, alternatives, and modifications. In some embodiments, nanostructures other than nanowires are utilized. In other embodiments, different electrode structures are used for electrode structure 930 and/or electrode structure 935. For example, electrode structure 295 as shown in FIG. 2, electrode structure 395 as shown in FIG. 3, electrode structure 495 as shown in FIG. 4, electrode structure 595 as shown in FIG. 5, and/or electrode structure 695 as shown in FIG. 6 is substituted for one or more of the electrode structures 930, 930A, 930B, 930C, 935, 935A, 935B, and/or 935C. In another example, any combination of different electrode structures are used for each of the electrode structures 930, 930A, 930B, 930C, 935, 935A, 935B, and/or 935C. In certain embodiments one or more substrates is used for the various thermoelectric device legs. For example, each of the thermoelectric device legs 900A, 900B, and 900C are formed in the same substrate. In another example, one or more of the thermoelectric device legs 900A, 900B, and/or 900C are formed in a different substrate. In some embodiments, the insulating layer 950AB and/or the insulating layer 955BC are omitted.

As discussed above and further emphasized here, FIGS. 7A, 7B, 8A, 8B, 9A and 9B are merely examples, which should not unduly limit the scope of the claims. One of ordinary skill in the art would recognize many variations, alternatives, and modifications. In some embodiments, different styles of thermoelectric legs are utilized in the same thermoelectric device. For example, a thermoelectric device includes thermoelectric device leg 700A, thermoelectric device leg 800B, and thermoelectric device leg 900C. In another example, any combination of thermoelectric device legs 700, 800, and/or 900 are included in the same thermoelectric device.

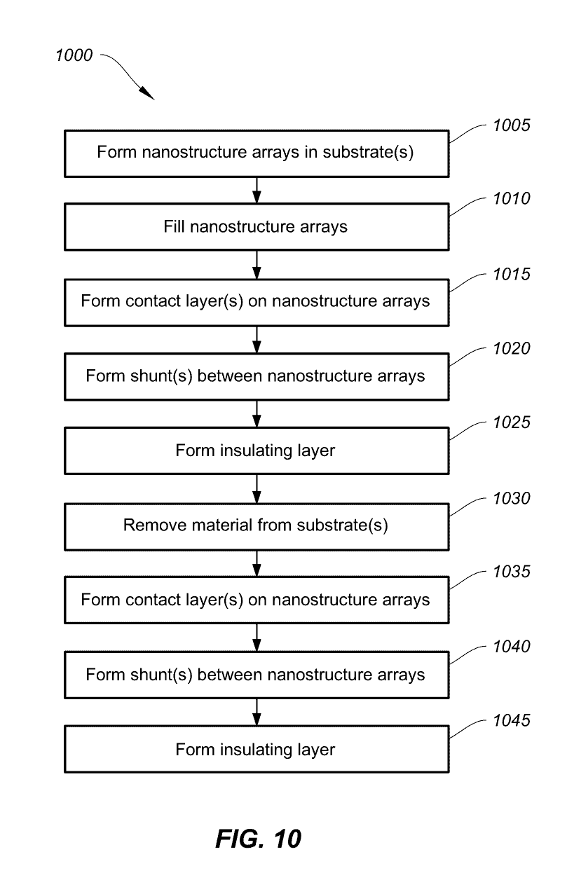

FIG. 10 is a simplified diagram showing a method for forming electrode structures on arrays of nanostructures according to one embodiment of the present invention. This diagram is merely an example, which should not unduly limit the scope of the claims. One of ordinary skill in the art would recognize many variations, alternatives, and modifications. The method 1000 includes a process 1005 for forming nanostructure arrays in one or more substrates, a process 1010 for filling the nanostructure arrays, a process 1015 for forming one or more contact layers on the nanostructure arrays, a process 1020 for forming one or more shunts between nanostructure arrays, a process 1025 for forming an insulating layer, a process 1030 for removing material from the one or more substrates, a process 1035 for forming one or more contact layers on the nanostructure arrays, a process 1040 for forming one or more shunts between the nanostructure arrays, and a process 1045 for forming an insulating layer. For example, the method 1000 is used to form the thermoelectric device leg 700 as shown in FIG. 7A and the thermoelectric device 790 as shown in FIG. 7B. In another example, one or more of the processes 1025 and/or 1045 are skipped. In yet another example, the process 1010 is skipped.

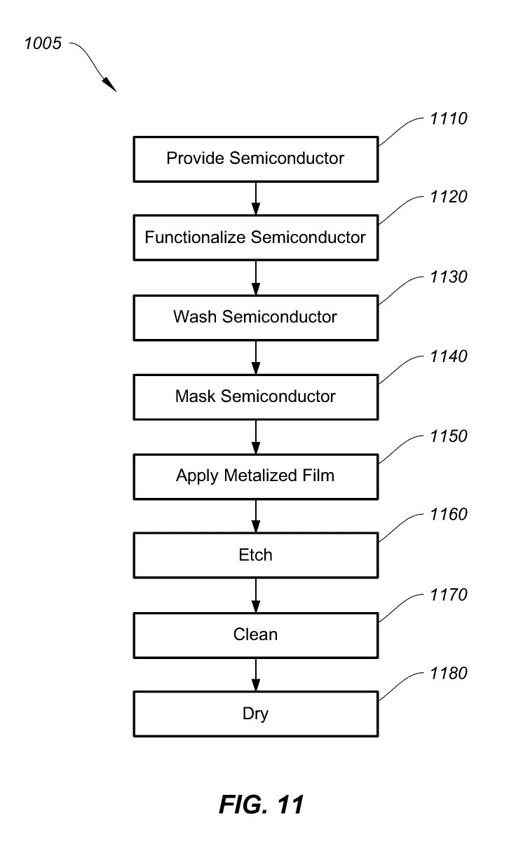

FIG. 11 is a simplified diagram showing the process 1005 for forming nanostructure arrays in one or more substrates as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. The process 1005 includes a process 1110 for providing the semiconductor substrate, a process 1120 for functionalizing the semiconductor substrate, a process 1130 for washing the semiconductor substrate, a process 1140 for masking portions of the semiconductor substrate, a process 1150 for applying a metalized film to the semiconductor substrate, a process 1160 for etching the semiconductor substrate, a process 1170 for cleaning the etched semiconductor substrate, and a process 1180 for drying the etched semiconductor substrate.

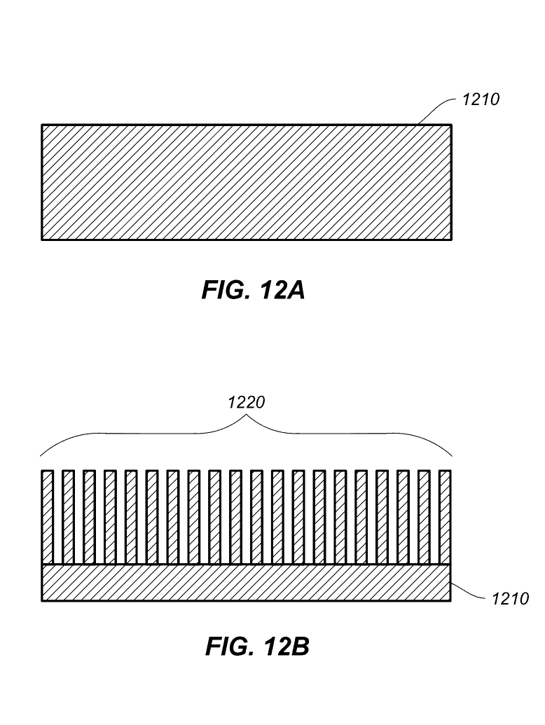

FIG. 12A is a simplified diagram showing a substrate used for the process 1110 for providing a substrate as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, the substrate 1210 is a block of semiconductor material (e.g., a semiconductor substrate). In another example, the semiconductor substrate 1210 is an entire wafer. In yet another example, the semiconductor substrate 1210 is a 4-inch wafer. In yet another example, the semiconductor substrate is a panel larger then a 4-inch wafer. In another example, the semiconductor substrate 1210 is a 6-inch wafer. In another example, the semiconductor substrate 1210 is an 8-inch wafer. In another example, the semiconductor substrate 1210 is a 12-inch wafer. In yet another example, the semiconductor substrate 1210 is a panel larger then a 12-inch wafer. In yet another example, the semiconductor substrate 1210 is in a shape other than that of a wafer. In yet another example, the semiconductor substrate 1210 is single-crystalline. In yet another example, the semiconductor substrate 1210 is poly-crystalline. In yet another example, the semiconductor substrate 1210 includes silicon.

In some embodiments, the semiconductor substrate 1210 is functionalized. For example, the semiconductor substrate 1210 is doped to form an n-type semiconductor. In another example, the semiconductor substrate 1210 is doped to form a p-type semiconductor. In yet another example, the semiconductor substrate 1210 is doped using Group III and/or Group V elements. In yet another example, the semiconductor substrate 1210 is functionalized to control the electrical and/or thermal properties of the semiconductor substrate 1210. In yet another example, the semiconductor substrate 1210 includes silicon doped with boron. In yet another example, the semiconductor substrate 1210 is doped to adjust the resistivity of the semiconductor substrate 1210 to between approximately 0.00001 Ω-m and 10 Ω-m. In yet another example, the semiconductor substrate 1210 is functionalized to adjust the thermal conductivity between 0.1 W/(m·K) (i.e., Watts per meter per degree Kelvin) and 500 W/(m·K).

FIG. 12B is a simplified diagram showing an array of nanostructures in a substrate as formed by the process 1005 as shown in FIG. 11 as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, the array of nanostructures 1220 is formed using the process 1005. In another example, the array of nanostructures 1220 is the array of nanowires 110 as shown in FIGS. 1-6 and/or the array of nanowires 710 as shown in FIG. 7A. In yet another example, the array of nanostructures 1220 is an array of nanoholes. In yet another example, the array of nanostructures 1220 is an array of nanotubes. In yet another example, the array of nanostructures 1220 is a nanomesh.

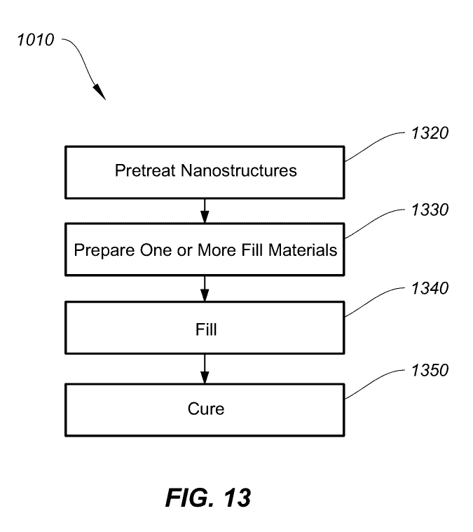

FIG. 13 is a simplified diagram showing the process 1010 for filling the array of nanostructures in a substrate as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. The optional process 1010 includes a process 1320 for pretreating the array of nanostructures, a process 1330 for preparing one or more fill materials, a process 1340 for filling the array of nanostructures, and a process 1350 for curing the one or more fill materials. For example, the process 1010 is used to at least partially fill the array of nanowires 110 as shown in FIGS. 1-6 and/or the array of nanowires 710 as shown in FIG. 7A. In yet another example, the process 1010 forms the one or more fill materials 160 as shown in FIGS. 1-6. In yet another example, the process 1010 is used to fill an array of nanoholes, an array of nanotubes, and/or a nanomesh. In yet another example, the processes 1320 and/or 1350 are skipped.

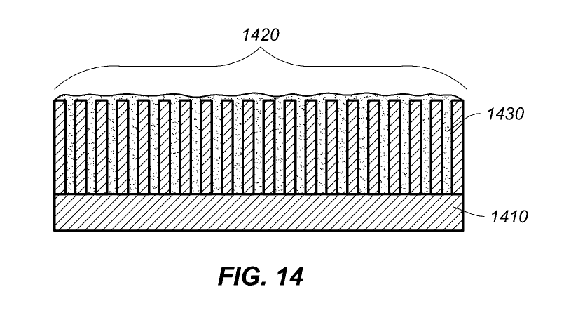

FIG. 14 is a simplified diagram of a filled array of nanostructures in a substrate as formed by the process 1010 of FIG. 13 as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, the array of nanostructures 1420 as formed in the substrate 1410 is filled with one or more fill materials 1430. In another example, the one or more fill materials 1430 are the one or more fill materials 160. In yet another example, the array of nanostructures 1420 is the array of nanostructures 110 and/or the array of nanostructures 710. In yet another example, the one or more fill materials 1430 each include at least one selected from a group consisting of photoresist, spin-on glass, spin-on dopant, aerogel, xerogel, and oxide, and the like. For example, the photoresist includes long UV wavelength G-line (e.g., approximately 436 nm) photoresist. In another example, the photoresist has negative photoresist characteristics. In yet another example, the photoresist exhibits good adhesion to various substrate materials, including Si, GaAs, InP, and glass. In yet another example, the photoresist exhibits good adhesion to various metals, including Au, Cu, and Al. In yet another example, the spin on glass has a high dielectric constant. In yet another example, the spin-on dopant includes n-type and/or p-type dopants. In yet another example, the spin-on dopant is applied regionally with different dopants in different areas of the array of nanowires 1420. In yet another example, the spin-on dopant includes boron and/or phosphorous and the like. In yet another example, the spin-on glass includes one or more spin-on dopants. In yet another example, the aerogel is derived from silica gel characterized by an extremely low thermal conductivity of about 0.1 W/(m·K) and lower. In yet another example, the one or more fill materials include long chains of one or more oxides. In yet another example, the one or more fill materials includes at least one selected from a group consisting of Al₂O₃, FeO, FeO₂, Fe₂O₃, TiO, TiO₂, ZrO₂, ZnO, HfO₂, CrO, Ta₂O₅, SiN, TiN, BN, SiO₂, AlN, CN, and/or the like.

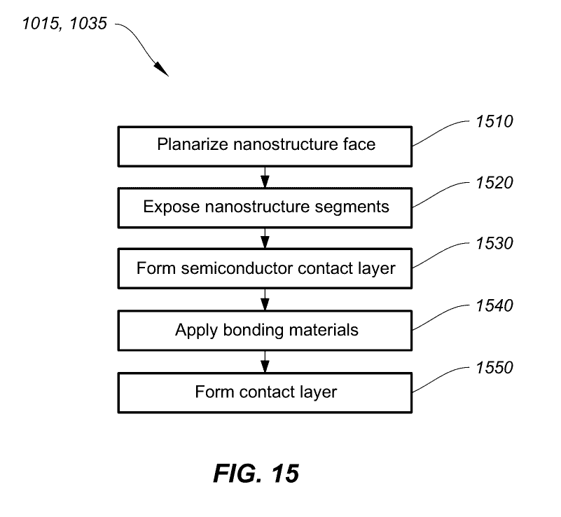

FIG. 15 is a simplified diagram showing a process 1015 and/or a process 1035 for forming one or more contact layers on the nanostructure arrays as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. The process 1015 and/or the process 1035 includes a process 1510 for planarizing the face of the nanostructures, a process 1520 for exposing segments of the nanostructures, a process 1530 for forming a semiconductor contact layer on the exposed segments of the nanostructures, a process 1540 for applying bonding materials, and a process 1550 for forming a contact layer. For example, the process 1015 and/or the process 1035 are used to form the semiconductor contact materials 160, the bonding materials 162, and/or the contact layer 164 as shown in FIGS. 1-6. In another example, one or more of the processes 1510, 1520, and/or 1540 are skipped. In yet another example, the processes 1530 and 1550 are combined into a single process.

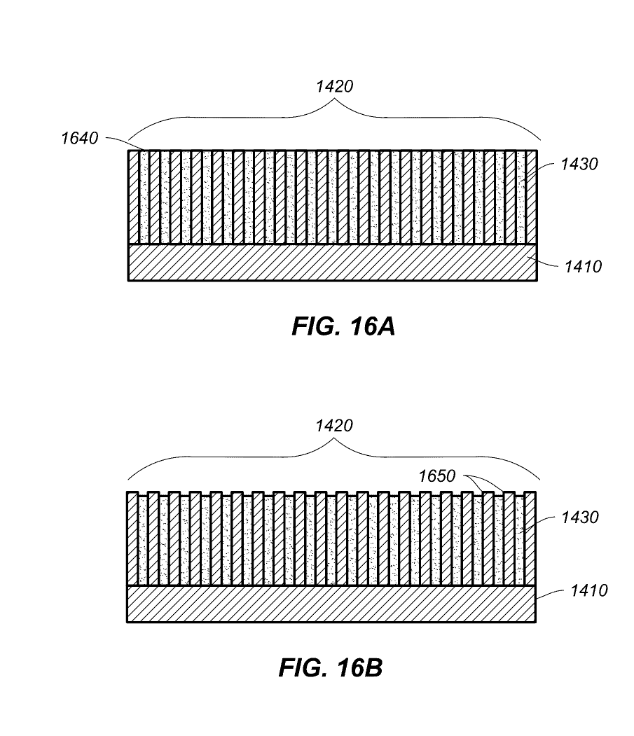

FIG. 16A is a simplified diagram of a filled and planarized array of nanostructures in a substrate as formed by the planarization process 1510 as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, at the optional process 1510 a filled array of nanostructures 1420 is planarized. In another example, at least one surface 1640 of the filled array of nanostructures 1420 is made substantially planar. In yet another example, the planarization process 1510 exposes ends of the array of nanostructures 1420. In yet another example, the planarization process 1510 includes at least one process selected from a group consisting of plasma etching, wet chemical etching, lapping, mechanical polishing, chemical mechanical polishing, spontaneous dry etching, and the like. In yet another example, the lapping process includes the use of a 6 μm diamond slurry with a copper base plate. In yet another example, the plasma etching uses SF₆ in a vacuum chamber. In yet another example, the spontaneous dry etching uses XeF₂ planarization process 1510 includes plasma etching. In yet another example, the planarization process 1510 prepares the filled array of nanostructures 1420 for further handling, machining, and/or manufacturing processes.

FIG. 16B is a simplified diagram of a filled and planarized array of nanostructures with exposed segments as formed by the process 1520 for exposing nanostructure segments as part of the method 1000 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, at the optional process 1520, exposed segments 1650 for each of the nanostructures in the array of nanostructures 1420 are formed. In another example, the exposed segments 1650 are the protruding segments 135 as shown in FIGS. 1-6, the protruding segments 720 as shown in FIG. 7A, and/or the protruding segments 725 as shown in FIG. 7A. In yet another example, the process 1520 for exposing the segments of the nanostructures includes removing a portion of the one or more fill materials 1430. In yet another example, the process 1520 for exposing the segments of the nanostructures includes etching using a HF solution. In yet another example, the HF solution includes at least one selected from a group consisting of a buffering agent, a surfactant, and other additives. In yet another example, the process 1520 for exposing the segments of the nanostructures includes etching in a reactive ion etcher.

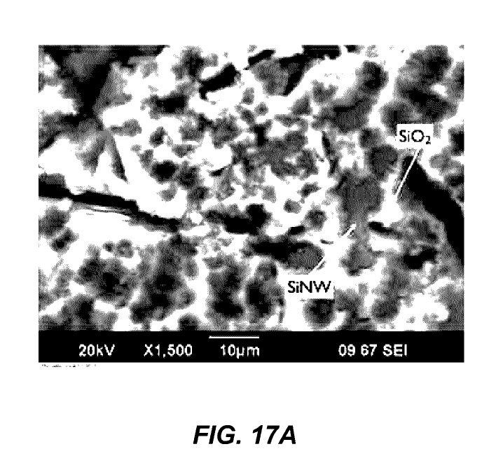

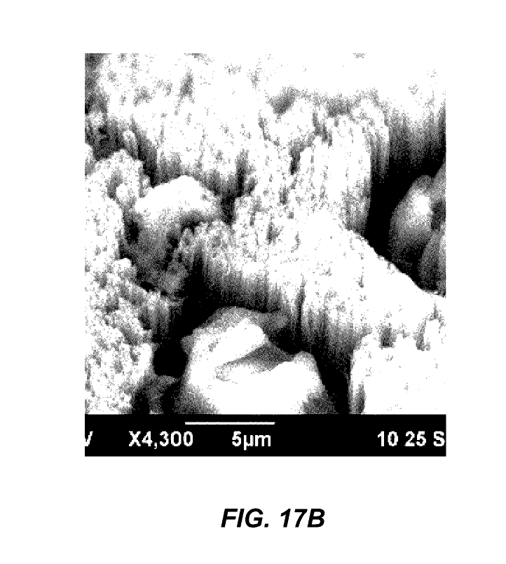

FIG. 17A is a scanning electron microscope image showing a surface of an array of nanostructures before exposure of the exposed segments of the array of nanostructures as part of the method 1000 for forming electrode structures on arrays of nanostructures according to one embodiment of the present invention. This image is merely an example, which should not unduly limit the scope of the claims. One of ordinary skill in the art would recognize many variations, alternatives, and modifications. As shown in FIG. 17A the exposed segments of the array of nanostructures are not well exposed. For example, the plurality of darker regions in FIG. 17A represent the nanostructures. In another example, the plurality of lighter regions in FIG. 17A represent the one or more fill materials. In yet another example, the presence of the one or more fill materials make the formation of high quality electrical and/or thermal contacts difficult. In yet another example, FIG. 17A depicts the array of nanostructures 1420 prior to the process 1520 for exposing segments of the nanostructures.

FIG. 17B is a scanning electron microscope image showing a surface of an array of nanostructures after exposure of the exposed segments of the array of nanostructures as part of the method 1000 for forming electrode structures on arrays of nanostructures according to one embodiment of the present invention. This image is merely an example, which should not unduly limit the scope of the claims. One of ordinary skill in the art would recognize many variations, alternatives, and modifications. As shown in FIG. 17B the exposed segments of the array of nanostructures are well exposed. For example, the exposed segments of the array of nanostructures are effectively protruding. In another example, FIG. 17B depicts the array of nanostructures 1420 after the process 1520 for exposing segments of the nanostructures.

Returning to FIG. 15, according to some embodiments, at the process 1530 a semiconductor contact layer is formed. For example, at the process 1530, the exposed segments 1650 of the nanostructures have semiconductor contact materials formed thereon. In another example, the semiconductor contact materials are the semiconductor contact materials 170 as shown in FIGS. 1-4. In yet another example, the process 1530 for forming the semiconductor contact layer includes at least one process selected from a group consisting of electrolytic plating, electroless plating, evaporation, sputtering, molecular beam epitaxy, chemical vapor deposition, atomic layer deposition, dipping, selective coating, and the like.

According to certain embodiments, the semiconductor contact materials include one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of Be, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like. In yet another example, the semiconductor contact materials include TiW in a 10 to 90 ratio. In yet another example, the semiconductor contact materials include TiW in a 10 to 90 ratio and Ni.

In yet another example, the semiconductor contact materials form one or more electric contacts with the segments 1650. In yet another example, the semiconductor contact materials form one or more ohmic contacts with the segments 1650. In yet another example, the semiconductor contact materials are configured to form one or more good thermal contacts with one or more surfaces for establishing one or more thermal paths through the array of nanostructures 1420 while limiting thermal leakage in the one or more fill materials 1430.

According to some embodiments, at the optional process 1540, bonding materials are applied to the semiconductor contact materials. In one example, the bonding materials form a layer between the semiconductor contact materials and a contact layer. In another example, the bonding materials are the bonding materials 172 as shown in FIGS. 1 and 2. In yet another example, the bonding materials include solder. In yet another example, the solder includes at least one material from the group consisting of Ag, Cu, Sn, Pb, Au, In, Cd, Zn, Bi, and the like. In yet another example, the bonding materials include a brazing material including at least one material from a group consisting of Ga, Ge, Si, Ag, Au, Pt, and the like. In yet another example, the bonding materials include silver-based metal adhesive. In yet another example, the bonding materials have a thickness of 100 nm or less. In yet another example, the bonding materials are formed using one or more processes selected from a group consisting of screen printing, sputtering, evaporation, paste dispensing, foils, and the like.

According to some embodiments, at the process 1550, a contact layer is formed. For example, the array of nanowires forms a portion of a leg of a thermoelectric device. For example, the contact layer is the contact layer 174 as shown in FIGS. 1-4. In another example, the process 1550 for forming the contact layer includes at least one process selected from a group consisting of electrolytic plating, electroless plating, evaporation, sputtering, molecular beam epitaxy, chemical vapor deposition, atomic layer deposition, dipping, selective coating, and the like.

According to certain embodiments, the contact layer includes one or more conductive materials. For example, the one or more conductive materials include at least one selected from a group consisting of semiconductors, semi-metals, metals, and the like. In another example, the semiconductors are each selected from a group consisting of Si, Ge, C, B, P, N, Ga, As, In, and the like. In yet another example, the semiconductors are doped. In yet another example, the semi-metals are selected from a group consisting of Be, Ge, Si, Sn, and the like. In yet another example, the metals are selected from a group consisting of Ti, Al, Cu, Au, Ag, Pt, Ni, P, B, Cr, Li, W, Mg, TiW, TiNi, TiN, Mo, TiSi, MoSi, WSi, and the like.

As discussed above and further emphasized here, FIG. 15 is merely an example, which should not unduly limit the scope of the claims. One of ordinary skill in the art would recognize many variations, alternatives, and modifications. In some embodiments, one or more processes for forming one or more diffusion barrier layers are also performed. For example, a diffusion barrier layer is formed between the protruding segments of the nanostructures and the semiconductor contact layer. In another example, a diffusion barrier layer is formed between the semiconductor contact layer and the bonding materials. In yet another example, a diffusion barrier layer is formed between the bonding materials and the contact layer. In some embodiments, the process 1540 for applying bonding materials is omitted and the process 1530 for forming a semiconductor contact layer and the process 1550 for forming the contact layer are combined. For example, this combined process forms the combined contact layer 570 as shown in FIGS. 5 and 6.

Returning to FIG. 10, according to some embodiments, at the process 1020, one or more shunts are formed between the nanostructure arrays. For example, each of the one or more shunts are the shunt 180 as shown in FIGS. 1-6, the shunt 740AB as shown in FIG. 7B, and/or the shunt 745BC as shown in FIG. 7B. In another example, each of the one or more shunts provides electrical connection between the one or more contact layers and other devices in a thermoelectric device. In yet another example, the other devices include one or more of the one or more contact layers of other legs of the thermoelectric device. In yet another example, each of the one or more shunts has a low sheet resistance. In yet another example, the sheet resistance is between 10¹⁰Ω/□ and 10Ω/□. In yet another example, the process 1020 includes at least one process selected from a group consisting of electrolytic plating, electroless plating, evaporation, sputtering, molecular beam epitaxy, chemical vapor deposition, atomic layer deposition, and the like. In yet another example, the chemical vapor deposition occurs at low pressure. In yet another example, the chemical vapor deposition is plasma enhanced. In yet another example, each of the one or more shunts includes one or more conductive materials. In yet another example, the one or more conductive materials include at least one selected from a group consisting of Ti, Al, Cu, Au, Ag, Pt, Ni, P, B, Cr, Li, W, Mg, TiW, TiNi, TiN, Mo, TiSi, MoSi, NiSi, WSi, graphite, steel, an alloy of nickel and iron, an alloy of cobalt, chromium, nickel, iron, molybdenum, and manganese, and the like. In yet another example, the alloy of nickel and iron is Alloy 42, which includes approximately 42% nickel, approximately 57% iron, and trace amounts of carbon, manganese, phosphorous, sulfur, silicon, chromium, aluminum, and/or cobalt by weight. In yet another example, the alloy of cobalt, chromium, nickel, iron, molybdenum, and manganese is Egiloy, which includes approximately 39-41% cobalt, approximately 19-21% chromium, approximately 14-16% nickel, approximately 11.3-20.5% iron, approximately 6-8% molybdenum, and/or approximately 1.5-2.5% manganese by weight. In yet another example, each of the one or more shunts has a thickness between 1 nm and 100,000 nm.

According to some embodiments, the process 1020 for forming one or more shunts between the nanostructure arrays includes an optional subprocess for applying one or more bonding materials. In one example, the bonding materials form a layer between the one or more contact layers and the one or more shunts. In another example, the bonding materials are the bonding materials 185 as shown in FIGS. 1, 3, and 5. In yet another example, the bonding materials include solder. In yet another example, the solder includes at least one material from the group consisting of Ag, Cu, Sn, Pb, Au, In, Cd, Zn, Bi, and the like. In yet another example, the bonding materials include a brazing material including at least one material from a group consisting of Ga, Ge, Si, Ag, Au, Pt, and the like. In yet another example, the bonding materials include silver-based metal adhesive. In yet another example, the bonding materials have a thickness of 100 nm or less. In yet another example, the bonding materials are formed using one or more processes selected from a group consisting of screen printing, sputtering, evaporation, paste dispensing, foils, and the like. In yet another example, the one or more shunts provide a secondary substrate to support the thermoelectric device legs during further processing steps.

According to some embodiments, at the optional process 1025, an insulating layer is formed on each of the one or more shunts. For example, the insulating layer includes one or more processes selected from a group consisting of chemical vapor deposition, low pressure chemical vapor deposition, plasma enhanced chemical vapor deposition, anodizing, and the like. For example, the insulating layer protects at least one of the shunts. For example, the insulating layer is the insulating layer 750AB and/or the insulating layer 755BC. In another example, the insulating layer provides electrical insulation to at least one of the shunts. In another example, the insulating layer reduces the likelihood that at least one of the shunts will be shorted against other conductive surfaces. In yet another example, the insulating layer has a high electrical resistance of at least 1 MΩ. In yet another example, the insulating layer has a thermal conductivity of at least 2 W/(m·K) (i.e., Watts per meter per degree Kelvin). In yet another example, the insulating layer has a thickness of 100 nm or less. In yet another example, the insulating layer includes one or more materials selected from a list consisting of SiO₂, Si₃N₄, SiN, Al₂O₃, and the like.

According to some embodiments, at the process 1030, material is removed from one or more of the substrates. For example, material from the one or more substrates in which the one or more arrays of nanostructures is formed, is removed. In another example, the one or more substrates are substantially removed. In yet another example, any of the one or more substrate is the substrate 1410 as shown in FIGS. 14 and 16.

In another example, the process 1530 for removing material includes coarse thinning. In yet another example, coarse thinning includes one or more processes selected from a group consisting of lapping, grinding, sanding, wet chemical etching, plasma etching, and spontaneous dry etching, and the like. In yet another example, spontaneous dry etching includes applying XeF₂ gas in a pressure controlled chamber. In yet another example, the coarse thinning removes a majority of the one or more substrates. In yet another example, the coarse thinning removes substantially all of the one or more substrates. In yet another example, the coarse thinning leaves behind less than 150 μm of the one or more substrates.

In some embodiments, the process 1530 for removing material includes fine thinning. For example, fine thinning includes one or more processes selected from a group consisting of plasma etching, wet chemical etching, lapping, mechanical polishing, chemical mechanical polishing, and spontaneous dry etching, and the like. In another example, spontaneous dry etching includes applying XeF₂ gas in a pressure controlled chamber. In yet another example, plasma etching includes applying SF₆ in a vacuum chamber. In yet another example, plasma etching includes applying SF₆ in a reactive ion etcher. In yet another example, the plasma etching is applied for a predetermined time period. In yet another example, the fine thinning process removes substantially all of the remaining portions of the one or more substrates. In yet another example, the fine thinning process removes up to 150 μm of the one or more substrates. In yet another example, the fine thinning process exposes at least some portion of the underlying one or more arrays of nanostructures. In yet another example, the fine thinning process removes a portion of the underlying one or more arrays of nanostructures.

According to some embodiments, at the process 1035, one or more contact layers are formed on the nanostructure arrays. For example, the process 1035 is substantially similar to the process 1015 as shown in FIG. 15. In another example, the one or more contact layers formed at the process 1035 use the same materials as the one or more contact layers formed at process 1015. In yet another example, the one or more contact layers formed at the process 1035 use different materials than the one or more contact layers formed at process 1015. In yet another example, the one or more contact layers formed at the process 1035 have a same layer structure as the one or more contact layers formed at the process 1015. In yet another example, the one or more contact layers formed at the process 1035 have a different layer structure than the one or more contact layers formed at the process 1015. In yet another example, the one or more contact layers formed at the process 1035 include semiconductor contact materials, bonding materials, and a contact layer and the one or more contact layers formed at the process 1015 include only a combined contact layer.

According to some embodiments, at the process 1040, one or more shunts are formed between the nanostructure arrays. For example, the process 1040 is substantially similar to the process 1020. In another example, the process 1040 forms the shunt 745BC and/or the shunt 740AB as shown in FIG. 7B. In yet another example, the one or more shunts formed at the process 1040 use the same materials as the one or more shunts formed at process 1020. In yet another example, the one or more shunts formed at the process 1040 use different materials than the one or more shunts formed at process 1020. In yet another example, the one or more shunts formed at the process 1040 have a same layer structure as the one or more shunts formed at the process 1020. In yet another example, the one or more shunts formed at the process 1040 have a different layer structure than the one or more shunts formed at the process 1020. In yet another example, the one or more shunts formed at the process 1040 include bonding materials and one or more shunts and the one or more shunts formed at the process 1020 include only one or more shunts.

According to some embodiments, at the optional process 1045 an insulating layer is formed on one or more shunts. For example, the process 1045 is substantially similar to the process 1025. In another example, the process 1045 forms the insulating layer 755BC and/or the insulating layer 750AB as shown in FIG. 7B. In yet another example, the insulating layer formed at the process 1045 uses the same materials as the insulating layer formed at process 1025. In yet another example, the insulating layer formed at the process 1045 uses different materials than the insulating layers formed at process 1025.

As discussed above and further emphasized here, FIG. 10 is merely an example, which should not unduly limit the scope of the claims. One of ordinary skill in the art would recognize many variations, alternatives, and modifications. In some embodiments, one or more processes for forming one or more diffusion barrier layers are also performed. For example, one or more diffusion barrier layers are formed between the one or more contact layers and/or the one or more shunts.

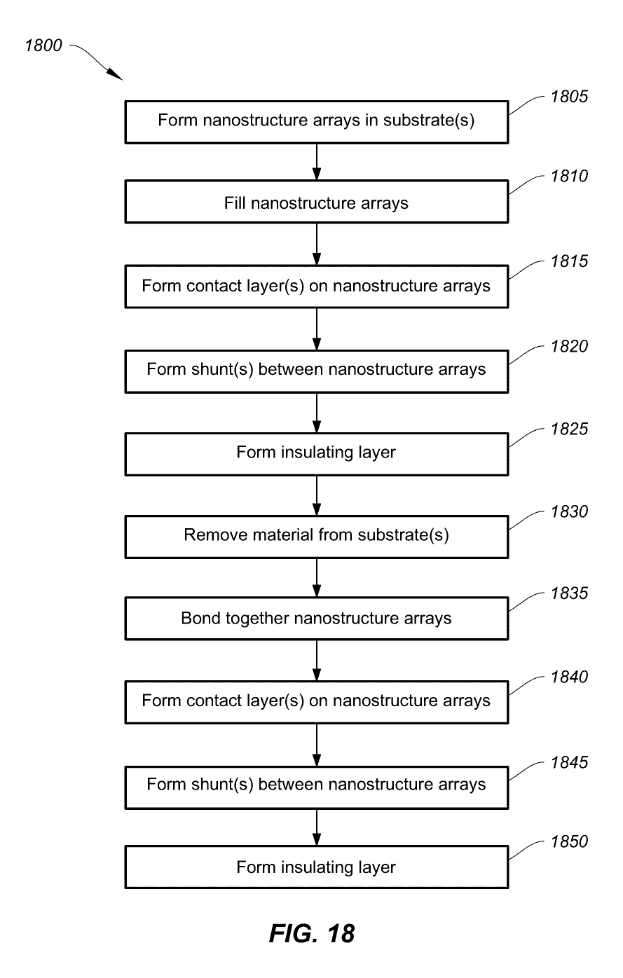

FIG. 18 is a simplified diagram showing a method for forming electrode structures on arrays of nanostructures according to another embodiment of the present invention. This diagram is merely an example, which should not unduly limit the scope of the claims. One of ordinary skill in the art would recognize many variations, alternatives, and modifications. The method 1800 includes a process 1805 for forming nanostructure arrays in one or more substrates, a process 1810 for filling the nanostructure arrays, a process 1815 for forming one or more contact layers on the nanostructure arrays, a process 1820 for forming one or more shunts between the nanostructure arrays, a process 1825 for forming an insulating layer, a process 1830 for removing material from the one or more substrates, a process 1835 for bonding together the nanostructure arrays, a process 1840 for forming one or more contact layers on the nanostructure arrays, a process 1845 for forming one or more shunts between nanostructure arrays, and a process 1850 for forming an insulating layer. For example, the method 1800 is used to form the thermoelectric device leg 800 as shown in FIG. 8A and the thermoelectric device 890 as shown in FIG. 8B. In another example, one or more of the processes 1810, 1825 and/or 1850 are skipped.

In some embodiments, at the process 1805, the nanostructure arrays are formed in one or more substrates. For example, the process 1805 is substantially similar to the process 1005 as shown in FIG. 11. In another example, during the process 1805, the process 1005 is used for form each of the nanostructure arrays separately. In yet another example, during the process 1805, the process 1005 is used to form the nanostructure arrays all at the same time. In yet another example, the nanostructure arrays are the nanowire array (e.g., thermoelectric segment) 810 and the nanowire array 815 as shown in FIG. 8A.

In some embodiments, at the optional process 1810, the nanostructure arrays are filled. For example, the process 1810 is substantially similar to the process 1010 as shown in FIG. 13. In another example, during the process 1810, the process 1010 is used to fill the nanostructure arrays with the same one or more fill materials. In yet another example, during the process 1810, the process 1010 is used to fill the nanostructure arrays with different one or more fill materials.

In certain embodiments, at the process 1815, one or more contact layers are formed on the nanostructure arrays. For example, the process 1815 is the process 1015 as shown in FIG. 15. In another example, the process 1815 forms one or more contact layers on the protruding segments 820 and/or the protruding segments 825 as shown in FIG. 8A.

According to some embodiments, at the process 1820, one or more shunts are formed between the nanostructure arrays. For example, the process 1820 is the process 1020. In another example, the process 1820 forms the shunt 840AB and/or the shunt 845BC as shown in FIG. 8B.

According to certain embodiments, at the optional process 1825, one or more insulating layers are formed. For example, the process 1825 is the process 1025. In another example, the process 1825 forms the insulating layer 850AB and/or the insulating layer 855BC as shown in FIG. 8B.

In some embodiments, at the process 1830, material is removed from one or more substrates. For example, the process 1830 is substantially similar to the process 1030. In another example, during the process 1830, the process 1030 is used to expose ends of the plurality of nanowires in the filled segment of nanowires 810 that are opposite to the protruding segments 820 as shown in FIG. 8A. In yet another example, during the process 1830, the process 1030 is used to expose ends of the plurality of nanowires in the filled segment of nanowires 815 that are opposite to the protruding segments 825 as shown in FIG. 8A.

In certain embodiments, at the process 1840, two or more nanostructure arrays are bonded together. For example, the two or more nanostructure arrays are bonded together using one or more processes selected from a group consisting of screen printing, sputtering, evaporation, paste dispensing, foils, and the like. In another example, the two or more nanostructure arrays are bonded together using segment bonding materials. In yet another example, the segment bonding materials include solder. In yet another example, the solder includes at least one material from the group consisting of Ag, Cu, Sn, Pb, Au, In, Cd, Zn, Bi, and the like. In yet another example, the segment bonding materials include a brazing material including at least one material from a group consisting of Ga, Ge, Si, Ag, Au, Pt, and the like. In yet another example, the segment bonding materials include silver-based metal adhesive.

In certain embodiments, at the process 1840, one or more contact layers are formed on the nanostructure arrays. For example, the process 1840 is the process 1035 as shown in FIG. 15. In another example, the process 1840 forms one or more contact layers on the protruding segments 825 and/or the protruding segments 820 as shown in FIG. 8A.

According to some embodiments, at the process 1845, one or more shunts are formed between the nanostructure arrays. For example, the process 1845 is the process 1040. In another example, the process 1845 forms the shunt 845BC and/or the shunt 840AB as shown in FIG. 8B.

According to certain embodiments, at the optional process 1850, one or more insulating layers are formed. For example, the process 1850 is the process 1045. In another example, the process 1850 forms the insulating layer 855BC and/or the insulating layer 850AB as shown in FIG. 8B.

As discussed above and further emphasized here, FIG. 18 is merely an example, which should not unduly limit the scope of the claims. One of ordinary skill in the art would recognize many variations, alternatives, and modifications. In some embodiments, one or more processes for forming one or more diffusion barrier layers are also performed. For example, one or more diffusion barrier layers are formed between the one or more contact layers and/or the one or more shunts. In some embodiments, a different variation of the one or more contact layers are formed in process 1815 from the one or more contact layers formed in process 1040. In some embodiments, a different variation of the one or more shunts are formed in process 1820 from the one or more shunts formed in process 1845. In certain embodiments, more than two segments of nanowire arrays are utilized in the thermoelectric device leg. For example, an additional segment of nanowires is bonded between the segment of nanowires 810 and the segment of nanowires 815 as shown in FIG. 8A.

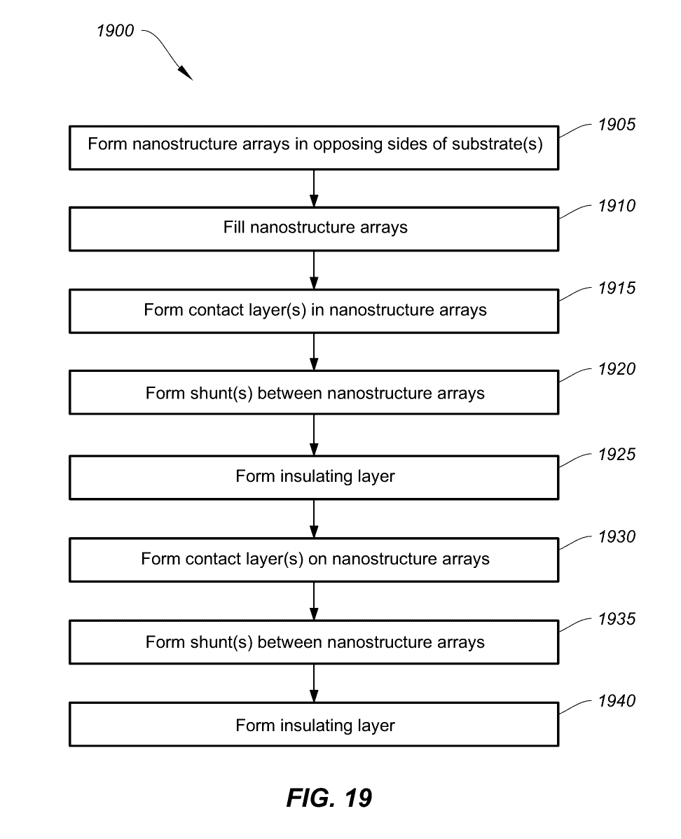

FIG. 19 is a simplified diagram showing a method for forming electrode structures on arrays of nanostructures according to another embodiment of the present invention. This diagram is merely an example, which should not unduly limit the scope of the claims. One of ordinary skill in the art would recognize many variations, alternatives, and modifications. The method 1900 includes a process 1905 for forming nanostructure arrays in opposing sides of one or more substrates, a process 1910 for filling the nanostructure arrays, a process 1915 for forming one or more contact layers on the nanostructure arrays, a process 1920 for forming one or more shunts between the nanostructure arrays, a process 1925 for forming an insulating layer, a process 1930 for forming one or more contact layers on the nanostructure arrays, a process 1935 for forming one or more shunts between nanostructure arrays, and a process 1940 for forming an insulating layer. For example, the method 1900 is used to form the thermoelectric device leg 900 as shown in FIG. 9A and the thermoelectric device 990 as shown in FIG. 9B. In another example, one or more of the processes 1910, 1925 and/or 1940 are skipped.

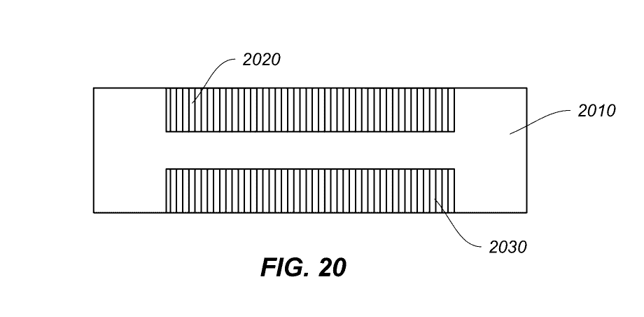

In some embodiments, at the process 1905, the nanostructure arrays are formed in opposing sides of one or more substrates. For example, the process 1905 is substantially similar to the process 1005 as shown in FIG. 11. FIG. 20 is a simplified diagram of a substrate with arrays of nanowires on opposing sides of a substrate as formed by the process 1905 as part of the method 1900 for forming electrode structures on arrays of nanostructures according to one embodiment of the present invention. This diagram is merely an example, which should not unduly limit the scope of the claims. One of ordinary skill in the art would recognize many variations, alternatives, and modifications. For example, an array of nanostructures 2020 is formed on a side of a substrate 2010 and another array of nanostructures 2030 is formed on an opposing side of the substrate 2010. In another example, the substrate 2010 is the substrate 980 as shown in FIG. 9A. In yet another example, the array of nanostructures 2020 is the array of nanowires 910 and/or the array of nanowires 915 as shown in FIG. 9A. In yet another example, the array of nanostructures 2030 is the array of nanowires 915 and/or the array of nanowires 910 as shown in FIG. 9A.

In some embodiments, at the optional process 1910, the nanostructure arrays are filled. For example, the process 1910 is substantially similar to the process 1010 as shown in FIG. 13. In another example, during the process 1910, the process 1010 is used to fill the nanostructure arrays with the same one or more fill materials. In yet another example, during the process 1910, the process 1010 is used to fill the nanostructure arrays with different one or more fill materials.

In certain embodiments, at the process 1915, one or more contact layers are formed on the nanostructure arrays. For example, the process 1915 is the process 1015 as shown in FIG. 15. In another example, the process 1915 forms one or more contact layers on the protruding segments 920 and/or the protruding segments 925 as shown in FIG. 9A.

According to some embodiments, at the process 1920, one or more shunts are formed between the nanostructure arrays. For example, the process 1920 is the process 1020. In another example, the process 1920 forms the shunt 940AB and/or the shunt 945BC as shown in FIG. 9B.

According to certain embodiments, at the optional process 1925, one or more insulating layers are formed. For example, the process 1925 is the process 1025. In another example, the process 1925 forms the insulating layer 950AB and/or the insulating layer 955BC as shown in FIG. 9B.

In certain embodiments, at the process 1930, one or more contact layers are formed on the nanostructure arrays. For example, the process 1930 is the process 1035 as shown in FIG. 15. In another example, the process 1930 forms one or more contact layers on the protruding segments 925 and/or the protruding segments 920 as shown in FIG. 9A.

According to some embodiments, at the process 1935, one or more shunts are formed between the nanostructure arrays. For example, the process 1935 is substantially similar to the process 1040. In another example, the process 1935 forms the shunt 945BC and/or the shunt 940AB as shown in FIG. 9B.

According to certain embodiments, at the optional process 1940, one or more insulating layers are formed. For example, the process 1940 is the process 1045. In another example, the process 1940 forms the insulating layer 955BC and/or the insulating layer 950AB as shown in FIG. 9B.

As discussed above and further emphasized here, FIG. 19 is merely an example, which should not unduly limit the scope of the claims. One of ordinary skill in the art would recognize many variations, alternatives, and modifications. In some embodiments, one or more processes for forming one or more diffusion barrier layers are also performed. For example, one or more diffusion barrier layers are formed between the one or more contact layers and/or the one or more shunts. In some embodiments, a different variation of the one or more contact layers are formed in process 1915 from the one or more contact layers formed in process 1930. In some embodiments, a different variation of the one or more shunts are formed in process 1920 from the one or more shunts formed in process 1935.

According to certain embodiments, a nanowire based thermoelectric device is provided with functionalized nanowire arrays sandwiched by a pair of electrode structures arranged for producing optimum thermoelectric generator (TEG) power. As an example, a device model is built to have an array of nanowires sandwiched by two electrode structures. In another example, let one electrode structure be in thermal contact with an exhaust heat exchanger (EHX) at a high inlet temperature (e.g., the temperature of a target heat source at, for example, 300° C.) and another electrode structure in touch with a coolant heat exchanger (CHX) at a low inlet temperature (e.g., a water coolant at about room temperature). In yet another example, a redundant array of nanowires sandwiched by two electrode structures is attached to the opposite side of the EHX in a mirrored, symmetric position. In yet another example, the device has a length Lₓ parallel to a flow stream (of the coolant, which is in counter-flow with EHX) and a width L_{y} perpendicular to the flow stream. In yet another example, a product of Lx and Ly gives a size A_{xy} of the device. In yet another example, the array of nanowires in both the array and the redundant array is assumed to have a wire length of about 200 μm and an effective cross sectional area for ranging from 100 to 0.01 mm². In yet another example, the electrode structures for both the array and the redundant array have a thickness ranging from 1 micron to 1000 microns and a contact resistivity of 2×10⁻⁹ Ohm cm². In yet another example, the electrode structures include Tungsten and associated electrical and thermal properties are applied. In yet another example, both EHX and CHX can be designed with certain standard features including spatially placed base plates with a plurality of heat dissipation fins. In yet another example, the EHX inlet temperature is 300 or 600 C.°. In yet another example, the array and the redundant array have a thermal conductivity of 90 W/(m·K).

According to certain embodiments, the device parameters of the array and the redundant array can be evaluated and optimized in terms of the TEG power value produced. For example, material selection of the electrode structures can be easily determined by directly comparing the TEG power for different materials. In another example, it has been found that Tungsten is a better choice compared to an alloy of nickel and iron (e.g., Alloy 42). In yet another example, optimum thickness of the electrode structures can also be determined.

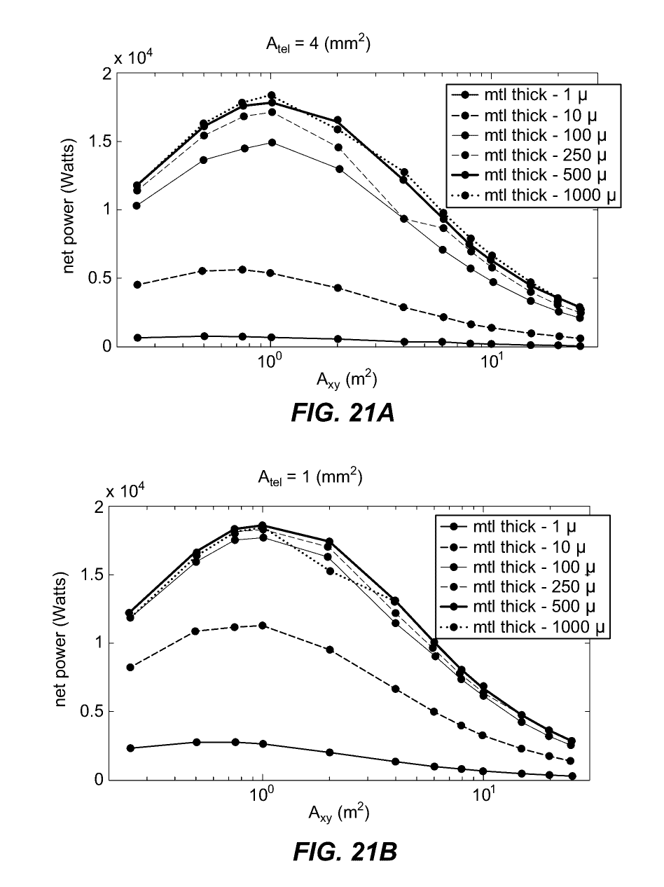

FIGS. 21A and 21B are simplified diagrams showing a plot of TEG power versus device size for different electrode structure thicknesses for a fixed thermoelectric cross-sectional area. These diagrams are merely an example, which should not unduly limit the scope of the claims. One of ordinary skill in the art would recognize many variations, alternatives, and modifications. For example, a nanowire array thickness (e.g., wire length) is set to be 200 μm and exhaust inlet temperature is set to be 600 C.°. In another example, with the electrode structure thicknesses of about 500 μm, the TEG power produced by the device is peaked for certain device size of A_{xy}.

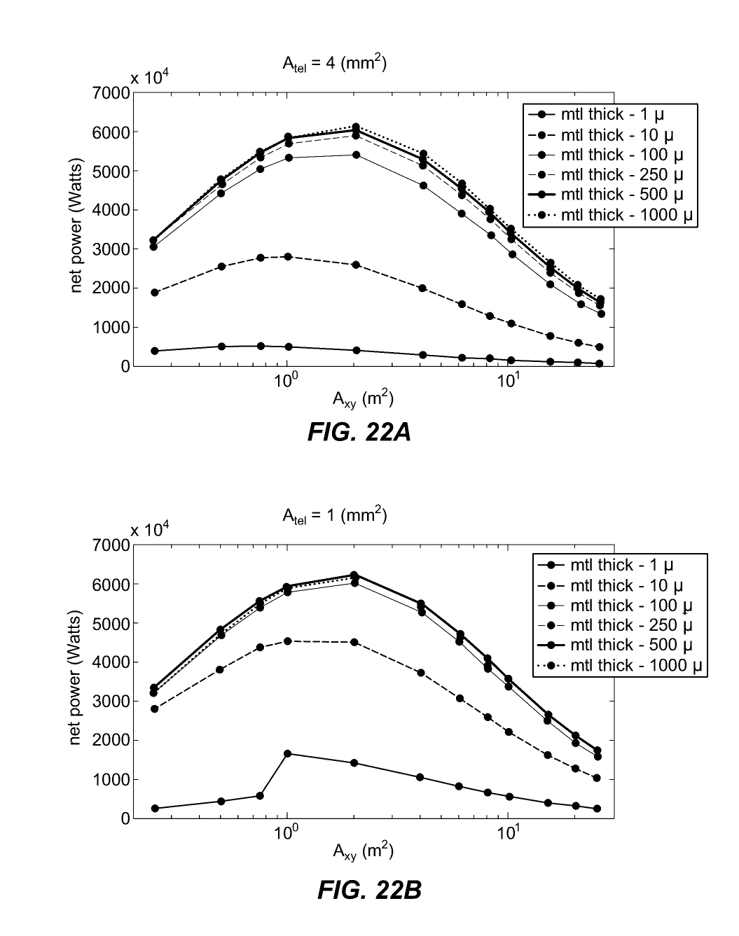

FIGS. 22A and 22B are simplified diagrams showing a plot of TEG power versus device size for different electrode structure thicknesses at a fixed cross-sectional area. These diagrams are merely an example, which should not unduly limit the scope of the claims. One of ordinary skill in the art would recognize many variations, alternatives, and modifications. For example, under nominal conditions, longer nanowire array thicknesses would lead to higher TEG power. In another example, the exhaust inlet temperature also plays an important role in affecting the TEG power production. In yet another example, the TEG power can be significantly higher with the exhaust inlet temperature at 600 C.° in comparison to an exhaust inlet temperature at 300 C.°, even though the nanowire array thickness has a smaller height of 200 μm in the former case compared to a larger height of 450 μm in the later. In yet another example, the nanowire array thickness is 450 μm and the exhaust inlet temperature is 300 C.°.

According to one embodiment, a thermoelectric device includes nanowires, a contact layer, and a shunt. Each of the nanowires includes a first end and a second end. The contact layer electrically couples the nanowires through at least the first end of each of the nanowires. The shunt is electrically coupled to the contact layer. All of the nanowires are substantially parallel to each other. A first contact resistivity between the first end and the contact layer ranges from 10⁻¹³ Ω-m² to 10⁻⁷ Ω-m². A first work function between the first end and the contact layer is less than 0.8 electron volts. The contact layer is associated with a first thermal resistance ranging from 10⁻² K/W to 10¹⁰ K/W. For example, the device is implemented according to at least FIGS. 1, 2, 3, 4, 5, and/or 6.

In another example, the device further includes one or more fill materials located between the nanowires and the nanowires are fixed in position relative to each other by the one or more fill materials. In yet another example, each of the nanowires further includes a first segment associated with the first end and a second segment associated with the second end, the second segment is substantially surrounded by the one or more fill materials, the first segment protrudes from the one or more fill materials, and the contact layer electrically couples the nanowires through at least the first segment of each of the nanowires. In yet another example, the one or more fill materials each include at least one material selected from a group consisting of photoresist, spin-on glass, spin-on dopant, aerogel, xerogel, nitride, and oxide. In yet another example, each of the one or more fill materials is associated with a thermal conductivity less than 50 Watts per meter per degree Kelvin. In yet another example, a distance between the first end and the second end is at least 300 μm. In yet another example, the distance is at least 525 μm. In yet another example, the nanowires correspond to an area, the area being smaller than 0.01 mm² in size. In yet another example, the nanowires correspond to an area, the area being at least 100 mm² in size. In yet another example, the device is associated with at least a sublimation temperature and a melting temperature, the sublimation temperature and the melting temperature being above 350° C. In yet another example, the melting temperature and the sublimation temperature are above 800° C.

In yet another example, the contact layer includes at least one or more materials selected form a group consisting of a semiconductor, a semi-metal, and a metal. In yet another example, the semiconductor includes at least one selected from a group consisting of Si, Ge, C, B, P, N, Ga, As, and In. In yet another example, the semi-metal includes at least one selected from a group consisting of B, Ge, Si, and Sn. In yet another example, the metal includes at least one selected from a group consisting of Ti, Al, Cu, Au, Ag, Pt, Ni, P, B, Cr, Li, W, Mg, TiW, TiNi, TiN, Mo, TiSi, MoSi, and WSi. In yet another example, the contact layer is associated with a thickness ranging from 1 nm to 100,000 nm. In yet another example, the shunt includes at least one or more materials selected form a group consisting of Ti, Al, Cu, Au, Ag, Pt, Ni, P, B, Cr, Li, W, Mg, TiW, TiNi, TiN, Mo, TiSi, MoSi, NiSi, WSi, graphite, steel, an alloy of nickel and iron, and an alloy of cobalt, chromium, nickel, iron, molybdenum, and manganese. In yet another example, the shunt is associated with a thickness ranging from 1 nm to 100,000 nm.

In yet another example, the device further includes a bonding layer coupling the contact layer and the shunt, and the bonding layer is associated with a sheet resistance ranging from 10¹⁰Ω per square and 10Ω per square and a thermal resistance ranging from 10⁻² K/W to 10¹⁰ K/W. In yet another example, the bonding layer includes one or more bonding materials selected from a group consisting of solder, brazing material, and silver-based metal adhesive. In yet another example, the device further includes an insulating layer formed on the shunt. In yet another example, the insulating layer includes one or more materials selected from a group consisting of SiO₂, Si₃N₄, SiN, and Al₂O₃. In yet another example, the shunt is configured to electrically couple the nanowires to one or more devices.

In yet another example, the contact layer includes one or more first contact materials coupled to at least the first end of each of the nanowires and one or more second contact materials electrically coupling each of the nanowires through at least the one or more first contact materials. A second contact resistivity between the first end and the one or more first contact materials ranges from 10⁻¹³ Ω-m² to 10⁻⁷ Ω-m². A second work function between the first end and the one or more first contact materials is less than 0.8 electron volts. The one or more first contact materials are associated with a second thermal resistance ranging from 10⁻² K/W to 10¹⁰ K/W. The one or more second contact materials are associated with a third thermal resistance ranging from 10⁻² K/W to 10¹⁰ K/W. In yet another example, the device further includes a bonding layer coupling the one or more first contact materials to the one or more second contact materials, and the bonding layer is associated with a sheet resistance ranging from 10⁻¹⁰Ω per square and 10Ω per square and a thermal resistance ranging from 10⁻² K/W to 10¹⁰ K/W.

In yet another example, the bonding layer includes one or more bonding materials selected from a group consisting of solder, brazing material, and silver-based metal adhesive. In yet another example, the first contact resistivity and the second contact resistivity are the same. In yet another example, the first work function and the second work function are the same. In yet another example, the one or more first contact materials and the one or more second contact materials are the same. In yet another example, the one or more first contact materials and the one or more second contact materials are different.

According to another embodiment, a thermoelectric device includes nanowires, a first electrode structure, and a second electrode structure. Each of the nanowires includes a first end and a second end opposite to the first end. The first electrode structure includes a first contact layer and a first shunt, the first contact layer electrically coupling the nanowires through at least the first end of each of the nanowires, the first shunt electrically coupled to the first contact layer. The second electrode structure includes a second contact layer and a second shunt, the second contact layer electrically coupling the nanowires through at least the second end of each of the nanowires, the second shunt electrically coupled to the second contact layer. All the nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the second end and the second contact layer ranges from 10⁻¹³ Ω-m² to 10⁻⁷ Ω-m². A second work function between the second end and the second contact layer is less than 0.8 electron volts. The second contact layer is associated with a second thermal resistance ranging from 10⁻² K/W to 10¹⁰ K/W. For example, the device is implemented according to a least FIGS. 7A and/or 7B.

In another example, the device further includes one or more first bonding materials coupling the first contact to the first shunt and one or more second bonding materials coupling the second contact to the second shunt. The one or more first bonding materials are associated with a first sheet resistance ranging from 10⁻¹⁰Ω per square to 10Ω per square and a third thermal resistance ranging from 10⁻² K/W to 10¹⁰ K/W. The one or more second bonding materials are associated with a second sheet resistance ranging from 10⁻¹⁰Ω per square to 10Ω per square and a fourth thermal resistance ranging from 10⁻² K/W to 10¹⁰ K/W. In yet another example, the first contact layer includes one or more first contact materials electrically coupled to at least the first end of each of the nanowires and one or more second contact materials, electrically coupling each of the nanowires through at least the one or more first contact materials. A third contact resistivity between the first end and the one or more first contact materials ranges from 10⁻¹³ Ω-m² to 10⁻⁷ Ω-m². A third work function between the first end and the one or more first contact materials is less than 0.8 electron volts. The one or more first contact materials are associated with a third thermal resistance ranging from 10⁻² K/W to 10¹⁰ K/W. The one or more second contact materials are associated with a fourth thermal resistance ranging from 10⁻² K/W to 10¹⁰ K/W.

In yet another example, the first shunt is configured to electrically couple the first end of each of the nanowires to one or more devices. In yet another example, the second shunt is configured to electrically couple the second end of each of the nanowires to one or more devices.

According to yet another embodiment, a thermoelectric device includes first nanowires, a first electrode structure, second nanowires different from the first nanowires, and a second electrode structure. Each of the first nanowires includes a first end and a second end opposite to the first end. The first electrode structure includes a first contact layer and a first shunt, the first contact layer electrically coupling the first nanowires through at least the first end of each of the first nanowires, the first shunt electrically coupled to the first contact layer. Each of the second nanowires includes a third end and a fourth end opposite to the third end. The second electrode structure includes a second contact layer and a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. The second end is electrically coupled to the fourth end. For example, the device is implemented according to at least FIGS. 8A and/or 8B.

In another example, the device further includes one or more bonding materials include a first side and a second side opposite to the first side. The first side is electrically coupled to the second end and the second side is electrically coupled to the fourth end. The one or more bonding materials are associated with a sheet resistance ranging from 10⁻¹⁰Ω per square to 10Ω per square and a third thermal resistance ranging from 10⁻² K/W to 10¹⁰ K/W. In yet another example, the one or more bonding materials are selected from a group consisting of solder, brazing material, and silver-based metal adhesive. In yet another example, the device further includes one or more first bonding materials coupling the first contact to the first shunt and one or more second bonding materials coupling the second contact to the second shunt. The one or more first bonding materials are associated with a first sheet resistance ranging from 10⁻¹⁰Ω per square to 10Ω per square and a third thermal resistance ranging from 10⁻² K/W to 10¹⁰ K/W. The one or more second bonding materials are associated with a second sheet resistance ranging from 10⁻¹⁰Ω per square to 10Ω per square and a fourth thermal resistance ranging from 10⁻² K/W to 10¹⁰ K/W.

According to yet another embodiment, a thermoelectric device includes first nanowires associated with a first side of a substrate, a first electrode structure, second nanowires associated with a second side of the substrate, and a second electrode structure. Each of the first nanowires includes a first end and a second end opposite to the first end. The first electrode structure includes a first contact layer and a first shunt, the first contact layer electrically coupling the first nanowires through at least the first end of each of the first nanowires, the first shunt electrically coupled to the first contact layer. The second nanowires being different from the first nanowires. The second side being opposite the first side. Each of the second nanowires includes a third end and a fourth end opposite to the third end. The second electrode structure includes a second contact layer and a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. For example, the device is implemented according to at least FIGS. 9A and/or 9B.

In another example, the device further includes one or more first bonding materials coupling the first contact to the first shunt and one or more second bonding materials coupling the second contact to the second shunt. The one or more first bonding materials are associated with a first sheet resistance ranging from 10⁻¹⁰Ω per square to 10Ω per square and a third thermal resistance ranging from 10⁻² K/W to 10¹⁰ K/W. The one or more second bonding materials are associated with a second sheet resistance ranging from 10⁻¹⁰Ω per square to 10Ω per square and a fourth thermal resistance ranging from 10⁻² K/W to 10¹⁰ K/W.

According to yet another embodiment, a method for making a thermoelectric device includes forming nanowires, depositing a contact layer, and forming a shunt. Each of the nanowires includes a first end and a second end. The contact layer electrically couples the nanowires through at least the first end of each of the nanowires. The shunt is electrically coupled to the contact layer. All of the nanowires are substantially parallel to each other. A first contact resistivity between the first end and the contact layer ranges from 10⁻¹³ Ω-m² to 10⁻⁷ Ω-m². A first work function between the first end and the contact layer is less than 0.8 electron volts. The contact layer is associated with a first thermal resistance ranging from 10⁻² K/W to 10¹⁰ K/W. For example, the method is implemented according to at least FIG. 10.

In another example, the method further includes bonding the contact layer to the shunt using one or more bonding materials. In yet another example, the method further includes forming an insulating layer on the shunt. In yet another example, the process for depositing the contact layer includes depositing one or more first contact materials on at least the first end of each of the nanowires and depositing one or more second contact materials electrically coupling each of the nanowires through at least the one or more first contact materials. A second contact resistivity between the first end and the one or more first contact materials ranges from 10⁻¹³ Ω-m² to 10⁻⁷ Ω-m². A second work function between the first end and the one or more first contact materials is less than 0.8 electron volts. The one or more first contact materials are associated with a second thermal resistance ranging from 10⁻² K/W to 10¹⁰ K/W. The one or more second contact materials are associated with a third thermal resistance ranging from 10⁻² K/W to 10¹⁰ K/W. In yet another example, the process for forming the contact layer further includes bonding the one or more first contact materials to the one or more second contact materials using one or more bonding materials.

According to yet another embodiment, a method for making a thermoelectric device includes forming nanowires, forming a first electrode structure, and forming a second electrode structure. Each of the nanowires includes a first end and a second end opposite to the first end. Forming the first electrode structure includes depositing a first contact layer and forming a first shunt, the first contact layer electrically coupling the nanowires through at least the first end of each of the nanowires, the first shunt electrically coupled to the first contact layer. Forming the second electrode structure includes depositing a second contact layer and forming a second shunt, the second contact layer electrically coupling the nanowires through at least the second end of each of the nanowires, the second shunt electrically coupled to the second contact layer. All the nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the second end and the second contact layer ranges from 10⁻¹³ Ω-m² to 10⁻⁷ Ω-m². A second work function between the second end and the second contact layer is less than 0.8 electron volts. The second contact layer is associated with a second thermal resistance ranging from 10⁻² K/W to 10¹⁰ K/W. For example, the method is implemented according to at least FIG. 10.

In yet another embodiment, a method for making a thermoelectric device includes forming first nanowires, forming a first electrode structure, forming second nanowires different from the first nanowires, forming a second electrode structure, and electrically coupling the second end to the fourth end. Each of the first nanowires includes a first end and a second end opposite to the first end. Forming the first electrode structure includes depositing a first contact layer and forming a first shunt, the first contact layer electrically coupling the first nanowires through at least the first end of each of the first nanowires, the first shunt electrically coupled to the first contact layer. Each of the second nanowires includes a third end and a fourth end opposite to the third end. Forming the second electrode structure includes depositing a second contact layer and forming a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. For example, the method is implemented according to at least FIG. 18.

In another example, the process for electrically coupling the second end and the fourth end includes bonding the second end to the fourth end using one or more boding materials. The one or more boding materials include a first side and a second side opposite to the first side. The first side is electrically coupled to the second end. The second side is electrically coupled to the fourth end. The one or more bonding materials are associated with a sheet resistance ranging from 10⁻¹⁰Ω per square to 10Ω per square and a third thermal resistance ranging from 10⁻² K/W to 10¹⁰ K/W. In yet another example, the method further includes forming third nanowires, each of the third nanowires includes a fifth end and a sixth end opposite to the fifth end. The process for electrically coupling the second end and the fourth end includes bonding the second end to the fifth end using one or more first bonding materials and bonding the fourth end to the sixth end using one or more second bonding materials. All the third nanowires are substantially parallel to each other.

According to yet another embodiment, a method for making a thermoelectric device includes forming first nanowires associated with a first side of a substrate, forming a first electrode structure, forming second wires associated with a second side of the substrate, and forming a second electrode structure. Each of the first nanowires includes a first end and a second end opposite to the first end. Forming the first electrode structure includes depositing a first contact layer and forming a first shunt, the first contact layer electrically coupling the first nanowires through at least the first end of each of the first nanowires, the first shunt electrically coupled to the first contact layer. The second nanowires are different from the first nanowires. The second side is opposite the first side. Each of the second nanowires includes a third end and a fourth end opposite to the third end. Forming the second electrode structure includes depositing a second contact layer and forming a second shunt, the second contact layer electrically coupling the second nanowires through at least the third end of each of the second nanowires, the second shunt electrically coupled to the second contact layer. All the first nanowires are substantially parallel to each other. All the second nanowires are substantially parallel to each other. A first contact resistivity between the first end and the first contact layer ranges from 10⁻¹³ Ω-m² to 10⁻⁷ Ω-m². A first work function between the first end and the first contact layer is less than 0.8 electron volts. The first contact layer is associated with a first thermal resistance ranging from 10⁻² K/W to 10¹⁰ K/W. A second contact resistivity between the third end and the second contact layer ranges from 10⁻¹³ Ω-m² to 10⁻⁷ Ω-m². A second work function between the third end and the second contact layer is less than 0.8 electron volts. The second contact layer is associated with a second thermal resistance ranging from 10⁻² K/W to 10¹⁰ K/W. For example, the method is implemented according to at least FIG. 19.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A thermoelectric device, the device comprising:
nanowires, each of the nanowires including a first end and a second end;
a contact layer electrically coupling the nanowires through at least the first end of each of the nanowires; and
a shunt electrically coupled to the contact layer;
wherein:
all of the nanowires are substantially parallel to each other;
a first contact resistivity between the first end and the contact layer ranges from 10⁻¹³ Ω-m² to 10⁻⁷ Ω-m²;
a first work function between the first end and the contact layer is less than 0.8 electron volts; and
the contact layer is associated with a first thermal resistance ranging from 10⁻² K/W to 10¹⁰ K/W.

2. The device of claim 1, and further comprising:
one or more fill materials located between the nanowires;
wherein the nanowires are fixed in position relative to each other by the one or more fill materials.

3. The device of claim 2 wherein:
each of the nanowires further includes a first segment associated with the first end and a second segment associated with the second end;
the second segment is substantially surrounded by the one or more fill materials;
the first segment protrudes from the one or more fill materials; and
the contact layer electrically couples the nanowires through at least the first segment of each of the nanowires.

4. The device of claim 2 wherein the one or more fill materials each include at least one material selected from a group consisting of photoresist, spin-on glass, spin-on dopant, aerogel, xerogel, nitride, and oxide.

5. The device of claim 2 wherein each of the one or more fill materials is associated with a thermal conductivity less than 50 Watts per meter per degree Kelvin.

6. The device of claim 1 wherein a distance between the first end and the second end is at least 300 μm.

7. The device of claim 6 wherein the distance is at least 525 μm.

8. The device of claim 1 wherein the nanowires correspond to an area, the area being smaller than 0.01 mm² in size.

9. The device of claim 1 wherein the nanowires correspond to an area, the area being at least 100 mm² in size.

10. The device of claim 1 wherein the device is associated with at least a sublimation temperature and a melting temperature, the sublimation temperature and the melting temperature being above 350° C.

11. The device of claim 10 wherein the melting temperature and the sublimation temperature are above 800° C.

12. The device of claim 1 wherein the contact layer includes at least one or more materials selected form a group consisting of a semiconductor, a semi-metal, and a metal.

13. The device of claim 12 wherein the semiconductor includes at least one selected from a group consisting of Si, Ge, C, B, P, N, Ga, As, and In.

14. The device of claim 12 wherein the semi-metal includes at least one selected from a group consisting of B, Ge, Si, and Sn.

15. The device of claim 12 wherein the metal includes at least one selected from a group consisting of Ti, Al, Cu, Au, Ag, Pt, Ni, P, B, Cr, Li, W, Mg, TiW, TiNi, TiN, Mo, TiSi, MoSi, and WSi.

16. The device of claim 1 wherein the contact layer is associated with a thickness ranging from 1 nm to 100,000 nm.

17. The device of claim 1 wherein the shunt includes at least one or more materials selected form a group consisting of Ti, Al, Cu, Au, Ag, Pt, Ni, P, B, Cr, Li, W, Mg, TiW, TiNi, TiN, Mo, TiSi, MoSi, NiSi, WSi, graphite, steel, an alloy of nickel and iron, and an alloy of cobalt, chromium, nickel, iron, molybdenum, and manganese.

18. The device of claim 1 wherein the shunt is associated with a thickness ranging from 1 nm to 100,000 nm.

19. The device of claim 1, and further comprising:
a bonding layer coupling the contact layer and the shunt;
wherein the bonding layer is associated with:
a sheet resistance ranging from 10⁻¹⁰Ω per square and 10Ω per square; and
a thermal resistance ranging from 10⁻² K/W to 10¹⁰ K/W.

20. The device of claim 19 wherein the bonding layer includes one or more bonding materials selected from a group consisting of solder, brazing material, and silver-based metal adhesive.

21. The device of claim 1, and further comprising an insulating layer formed on the shunt.

22. The device of claim 21 wherein the insulating layer includes one or more materials selected from a group consisting of SiO₂, Si₃N₄, SiN, and Al₂O₃.

23. The device of claim 1 wherein the shunt is configured to electrically couple the nanowires to one or more devices.

24. The device of claim 1 wherein the contact layer includes:
one or more first contact materials coupled to at least the first end of each of the nanowires; and
one or more second contact materials electrically coupling each of the nanowires through at least the one or more first contact materials;
wherein:
a second contact resistivity between the first end and the one or more first contact materials ranges from 10⁻¹³ Ω-m² to 10⁻⁷ Ω-m²;
a second work function between the first end and the one or more first contact materials is less than 0.8 electron volts;
the one or more first contact materials are associated with a second thermal resistance ranging from 10⁻² K/W to 10¹⁰ K/W; and
the one or more second contact materials are associated with a third thermal resistance ranging from 10⁻² K/W to 10¹⁰ K/W.

25. The device of claim 24, and further comprising:
a bonding layer coupling the one or more first contact materials to the one or more second contact materials;
wherein the bonding layer is associated with:
a sheet resistance ranging from 10⁻¹⁰Ω per square and 10Ω per square; and
a thermal resistance ranging from 10⁻² K/W to 10¹⁰ K/W.

26. The device of claim 25 wherein the bonding layer includes one or more bonding materials selected from a group consisting of solder, brazing material, and silver-based metal adhesive.

27. The device of claim 24 wherein the first contact resistivity and the second contact resistivity are the same.

28. The device of claim 24 wherein the first work function and the second work function are the same.

29. The device of claim 24 wherein the one or more first contact materials and the one or more second contact materials are the same.

30. The device of claim 24 wherein the one or more first contact materials and the one or more second contact materials are different.

31. A thermoelectric device, the device comprising:
nanowires, each of the nanowires including a first end and a second end opposite to the first end;
a first electrode structure including a first contact layer and a first shunt, the first contact layer electrically coupling the nanowires through at least the first end of each of the nanowires, the first shunt electrically coupled to the first contact layer; and
a second electrode structure including a second contact layer and a second shunt, the second contact layer electrically coupling the nanowires through at least the second end of each of the nanowires, the second shunt electrically coupled to the second contact layer;
wherein:
all the nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the second end and the second contact layer ranges from 10⁻¹³ Ω-m² to 10⁻⁷ Ω-m²;
a second work function between the second end and the second contact layer is less than 0.8 electron volts;
the second contact layer is associated with a second thermal resistance ranging from 10⁻² K/W to 10¹⁰ K/W.

32. The device of claim 31, and further comprising:
one or more first bonding materials coupling the first contact to the first shunt; and
one or more second bonding materials coupling the second contact to the second shunt;
wherein the one or more first bonding materials are associated with:
a first sheet resistance ranging from 10⁻¹⁰Ω per square to 10Ω per square; and
a third thermal resistance ranging from 10⁻² K/W to 10¹⁰ K/W;
wherein the one or more second bonding materials are associated with:
a second sheet resistance ranging from 10⁻¹⁰Ω per square to 10Ω per square; and
a fourth thermal resistance ranging from 10⁻² K/W to 10¹⁰ K/W.

33. The device of claim 31 wherein the first contact layer includes:
one or more first contact materials electrically coupled to at least the first end of each of the nanowires; and
one or more second contact materials, electrically coupling each of the nanowires through at least the one or more first contact materials;
wherein:
a third contact resistivity between the first end and the one or more first contact materials ranges from 10⁻¹³ Ω-m² to 10⁻⁷ Ω-m²;
a third work function between the first end and the one or more first contact materials is less than 0.8 electron volts;
the one or more first contact materials are associated with a third thermal resistance ranging from 10⁻² K/W to 10¹⁰ K/W; and
the one or more second contact materials are associated with a fourth thermal resistance ranging from 10⁻² K/W to 10¹⁰ K/W.

34. The device of claim 31 wherein the first shunt is configured to electrically couple the first end of each of the nanowires to one or more devices.

35. The device of claim 31 wherein the second shunt is configured to electrically couple the second end of each of the nanowires to one or more devices.

36. A thermoelectric device, the device comprising:
first nanowires, each of the first nanowires including a first end and a second end opposite to the first end;
a first electrode structure including a first contact layer and a first shunt, the first contact layer electrically coupling the first nanowires through at least the first end of each of the first nanowires, the first shunt electrically coupled to the first contact layer;
second nanowires different from the first nanowires, each of the second nanowires including a third end and a fourth end opposite to the third end; and
a second electrode structure including a second contact layer and a second shunt, the second contact layer electrically coupling the second nanowires through at least the third end of each of the second nanowires, the second shunt electrically coupled to the second contact layer;
wherein:
all the first nanowires are substantially parallel to each other;
all the second nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the third end and the second contact layer ranges from 10⁻¹³ Ω-m² to 10⁻⁷ Ω-m²;
a second work function between the third end and the second contact layer is less than 0.8 electron volts;
the second contact layer is associated with a second thermal resistance ranging from 10⁻² K/W to 10¹⁰ K/W; and
the second end is electrically coupled to the fourth end.

37. The device of claim 36, and further comprising:
one or more bonding materials including a first side and a second side opposite to the first side;
wherein:
the first side is electrically coupled to the second end; and
the second side is electrically coupled to the fourth end;
wherein the one or more bonding materials are associated with:
a sheet resistance ranging from 10¹⁰Ω per square to 10Ω per square; and
a third thermal resistance ranging from 10⁻² K/W to 10¹⁰ K/W.

38. The device of claim 37 wherein the one or more bonding materials are selected from a group consisting of solder, brazing material, and silver-based metal adhesive.

39. The device of claim 36, and further comprising:
one or more first bonding materials coupling the first contact to the first shunt; and
one or more second bonding materials coupling the second contact to the second shunt;
wherein the one or more first bonding materials are associated with:
a first sheet resistance ranging from 10¹⁰Ω per square to 10Ω per square; and
a third thermal resistance ranging from 10⁻² K/W to 10¹⁰ K/W;
wherein the one or more second bonding materials are associated with:
a second sheet resistance ranging from 10¹⁰Ω per square to 10Ω per square; and
a fourth thermal resistance ranging from 10⁻² K/W to 10¹⁰ K/W.

40. A thermoelectric device, the device comprising:
first nanowires associated with a first side of a substrate, each of the first nanowires including a first end and a second end opposite to the first end;
a first electrode structure including a first contact layer and a first shunt, the first contact layer electrically coupling the first nanowires through at least the first end of each of the first nanowires, the first shunt electrically coupled to the first contact layer;
second nanowires associated with a second side of the substrate, the second nanowires being different from the first nanowires, the second side being opposite the first side, each of the second nanowires including a third end and a fourth end opposite to the third end; and
a second electrode structure including a second contact layer and a second shunt, the second contact layer electrically coupling the second nanowires through at least the third end of each of the second nanowires, the second shunt electrically coupled to the second contact layer;
wherein:
all the first nanowires are substantially parallel to each other;
all the second nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the third end and the second contact layer ranges from 10⁻¹³ Ω-m² to 10⁻⁷ Ω-m²;
a second work function between the third end and the second contact layer is less than 0.8 electron volts; and
the second contact layer is associated with a second thermal resistance ranging from 10⁻² K/W to 10¹⁰ K/W.

41. The device of claim 40, and further comprising:
one or more first bonding materials coupling the first contact to the first shunt; and
one or more second bonding materials coupling the second contact to the second shunt;
wherein the one or more first bonding materials are associated with:
a first sheet resistance ranging from 10¹⁰Ω per square to 10Ω per square; and
a third thermal resistance ranging from 10⁻² K/W to 10¹⁰ K/W;
wherein the one or more second bonding materials are associated with:
a second sheet resistance ranging from 10⁻¹⁰Ω per square to 10Ω per square; and
a fourth thermal resistance ranging from 10⁻² K/W to 10¹⁰ K/W.

42. A method for making a thermoelectric device, the method comprising:
forming nanowires, each of the nanowires including a first end and a second end;
depositing a contact layer electrically coupling the nanowires through at least the first end of each of the nanowires; and
forming a shunt electrically coupled to the contact layer;
wherein:
all of the nanowires are substantially parallel to each other;
a first contact resistivity between the first end and the contact layer ranges from 10⁻¹³ Ω-m² to 10⁻⁷ Ω-m²;
a first work function between the first end and the contact layer is less than 0.8 electron volts; and
the contact layer is associated with a first thermal resistance ranging from 10⁻² K/W to 10¹⁰ K/W.

43. The method of claim 42, and further comprising bonding the contact layer to the shunt using one or more bonding materials.

44. The method of claim 42, and further comprising forming an insulating layer on the shunt.

45. The method of claim 42 wherein the process for depositing the contact layer includes:
depositing one or more first contact materials on at least the first end of each of the nanowires; and
depositing one or more second contact materials electrically coupling each of the nanowires through at least the one or more first contact materials;
wherein:
a second contact resistivity between the first end and the one or more first contact materials ranges from 10⁻¹³ Ω-m² to 10⁻⁷ Ω-m²;
a second work function between the first end and the one or more first contact materials is less than 0.8 electron volts;
the one or more first contact materials are associated with a second thermal resistance ranging from 10⁻² K/W to 10¹⁰ K/W; and
the one or more second contact materials are associated with a third thermal resistance ranging from 10⁻² K/W to 10¹⁰ K/W.

46. The method of claim 45 wherein the process for forming the contact layer further includes bonding the one or more first contact materials to the one or more second contact materials using one or more bonding materials.

47. A method for making a thermoelectric device, the method comprising:
forming nanowires, each of the nanowires including a first end and a second end opposite to the first end;
forming a first electrode structure including depositing a first contact layer and forming a first shunt, the first contact layer electrically coupling the nanowires through at least the first end of each of the nanowires, the first shunt electrically coupled to the first contact layer; and
forming a second electrode structure including depositing a second contact layer and forming a second shunt, the second contact layer electrically coupling the nanowires through at least the second end of each of the nanowires, the second shunt electrically coupled to the second contact layer;
wherein:
all the nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the second end and the second contact layer ranges from 10⁻¹³ Ω-m² to 10⁻⁷ Ω-m²;
a second work function between the second end and the second contact layer is less than 0.8 electron volts;
the second contact layer is associated with a second thermal resistance ranging from 10⁻² K/W to 10¹⁰ K/W.

48. A method for making a thermoelectric device, the method comprising:
forming first nanowires, each of the first nanowires including a first end and a second end opposite to the first end;
forming a first electrode structure including depositing a first contact layer and forming a first shunt, the first contact layer electrically coupling the first nanowires through at least the first end of each of the first nanowires, the first shunt electrically coupled to the first contact layer;
forming second nanowires different from the first nanowires, each of the second nanowires including a third end and a fourth end opposite to the third end;
forming a second electrode structure including depositing a second contact layer and forming a second shunt, the second contact layer electrically coupling the second nanowires through at least the third end of each of the second nanowires, the second shunt electrically coupled to the second contact layer; and
electrically coupling the second end to the fourth end;
wherein:
all the first nanowires are substantially parallel to each other;
all the second nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the third end and the second contact layer ranges from 10⁻¹³ Ω-m² to 10⁻⁷ Ω-m²;
a second work function between the third end and the second contact layer is less than 0.8 electron volts; and
the second contact layer is associated with a second thermal resistance ranging from 10⁻² K/W to 10¹⁰ K/W.

49. The method of claim 48 wherein the process for electrically coupling the second end and the fourth end includes bonding the second end to the fourth end using one or more boding materials including a first side and a second side opposite to the first side;
wherein:
the first side is electrically coupled to the second end; and
the second side is electrically coupled to the fourth end;
wherein the one or more bonding materials are associated with:
a sheet resistance ranging from 10¹⁰Ω per square to 10Ω per square; and
a third thermal resistance ranging from 10⁻² K/W to 10¹⁰ K/W.

50. The method of claim 48, and further comprising:
forming third nanowires, each of the third nanowires including a fifth end and a sixth end opposite to the fifth end;
wherein the process for electrically coupling the second end and the fourth end includes:
bonding the second end to the fifth end using one or more first bonding materials; and
bonding the fourth end to the sixth end using one or more second bonding materials;
wherein all the third nanowires are substantially parallel to each other.

51. A method for making a thermoelectric device, the method comprising:
forming first nanowires associated with a first side of a substrate, each of the first nanowires including a first end and a second end opposite to the first end;
forming a first electrode structure including depositing a first contact layer and forming a first shunt, the first contact layer electrically coupling the first nanowires through at least the first end of each of the first nanowires, the first shunt electrically coupled to the first contact layer;
forming second nanowires associated with a second side of the substrate, the second nanowires being different from the first nanowires, the second side being opposite the first side, and each of the second nanowires including a third end and a fourth end opposite to the third end; and
forming a second electrode structure including depositing a second contact layer and forming a second shunt, the second contact layer electrically coupling the second nanowires through at least the third end of each of the second nanowires, the second shunt electrically coupled to the second contact layer;
wherein:
all the first nanowires are substantially parallel to each other;
all the second nanowires are substantially parallel to each other;
a first contact resistivity between the first end and the first contact layer ranges from 10⁻¹³ Ω-m² to 10⁻⁷ Ω-m²;
a first work function between the first end and the first contact layer is less than 0.8 electron volts;
the first contact layer is associated with a first thermal resistance ranging from 10⁻² K/W to 10¹⁰ K/W;
a second contact resistivity between the third end and the second contact layer ranges from 10⁻¹³ Ω-m² to 10⁻⁷ Ω-m²;
a second work function between the third end and the second contact layer is less than 0.8 electron volts; and
the second contact layer is associated with a second thermal resistance ranging from 10⁻² K/W to 10¹⁰ K/W.
